(19) United States
(12) Patent Application Publication
(10) Pub. No.: US 2025/0056776 A1
(43) Pub. Date: Feb. 13, 2025

(54) ELECTROMAGNETIC-WAVE-ABSORBING FILM AND ITS PRODUCTION APPARATUS, AND NEAR-FIELD ELECTROMAGNETIC WAVE ABSORBER COMPRISING SUCH ELECTROMAGNETIC-WAVE-ABSORBING FILM

(71) Applicant: Seiji KAGAWA, Koshigaya-shi (JP)

(72) Inventors: Seiji Kagawa, Koshigaya-shi (JP); Yoichiro KAGAWA, Koshigaya-shi (JP)

(73) Assignee: Seiji KAGAWA, Koshigaya-shi (JP)

(21) Appl. No.: 18/624,603

(22) Filed: Apr. 2, 2024

(30) Foreign Application Priority Data
Aug. 7, 2023 (JP) 2023-128605

(51) Int. Cl. H05K 9/00; H01B 13/00

(52) U.S. Cl. CPC H05K 9/0086; H01B 13/0036

(57) ABSTRACT

An electromagnetic-wave-absorbing film comprising a plastic film and a thin metal film formed on a surface of the plastic film, the thin metal film being provided with large numbers of substantially parallel linear scratches with irregular widths and intervals in two directions, the linear scratches having high-density regions and low-density regions alternately in each direction, and the high-density regions being distributed in a lattice pattern by the crossing of linear scratches in both directions.

### FIELD OF THE INVENTION

The present invention relates to an electromagnetic-wave-absorbing film and a near-field electromagnetic wave absorber having high radiation noise absorbability in a wide frequency range of 100 MHz to 5 GHz, for example, and usable without connection to a ground, and an apparatus for producing such electromagnetic-wave-absorbing film.

### BACKGROUND OF THE INVENTION

To prevent malfunctions, etc. due to electromagnetic noises leaking from electronic devices in various electronic appliances and communications terminals, various electromagnetic wave absorbers have been put into practical use. In such circumstance, the inventor proposed by Japanese Patent 4685977 a composite film of a linearly-scratched thin metal film and a plastic film having decreased anisotropy of electromagnetic wave absorbability, which comprises a plastic film, and a single- or multi-layer thin metal film formed on at least one surface of the plastic film, the thin metal film being provided with large numbers of substantially parallel, intermittent, linear scratches with irregular widths and intervals in two directions. Japanese Patent 4685977 describes that improved electromagnetic wave absorbability is obtained by laminating pluralities of composite films each having a linearly-scratched thin metal film and a plastic film directly or via dielectric layers. Though the composite film of a linearly-scratched thin metal film and a plastic film in Japanese Patent 4685977 has excellent conductive noise absorbability in a wide frequency range, its radiation noise absorbability in a frequency range of less than 1 GHz is not necessarily sufficient.

Japanese Patent 5203295 discloses an electromagnetic-wave-absorbing film obtained by laminating a magnetic composite film comprising a plastic film and a thin magnetic metal film formed on at least one surface of the plastic film with a non-magnetic composite film comprising a plastic film and a thin non-magnetic metal film formed on at least one surface of the plastic film, at least one of the thin magnetic metal film and the thin non-magnetic metal film being provided with large numbers of substantially parallel, intermittent, linear scratches with irregular lengths, widths and intervals in at least one direction, the linear scratches having an average width of 1-100 μm and an average interval of 1-100 μm, 90% or more of the linear scratches having widths in a range of 0.1-1,000 μm. Japanese Patent 5203295 describes that an electromagnetic-wave-absorbing film comprising a thin magnetic metal film having a surface resistance of 1-377 Ω/square and a thin non-magnetic metal film having a surface resistance of 377-10,000 Ω/square has excellent near-field electromagnetic wave noise absorbability.

However, it has been found that electromagnetic noise absorption in Japanese Patent 5203295 is so-called conductive noise absorption, and that with respect to radiation noises in a wide frequency range from less than 1 GHz to single-digit GHz, there are frequencies at which they are maximized. Accordingly, when this electromagnetic-wave-absorbing film is put into practical use, it should be connected to a ground (GND) to prevent the radiation of the maximized noises.

WO 2012/090586 A discloses a near-field electromagnetic wave absorber obtained by adhering pluralities of electromagnetic-wave-absorbing films each comprising a thin metal film formed on one surface of a plastic film, the thin metal film of at least one electromagnetic-wave-absorbing film having a thin magnetic metal layer, and the thin metal film of at least one electromagnetic-wave-absorbing film being provided with large numbers of substantially parallel, intermittent, linear scratches with irregular widths and intervals in two directions. WO 2012/090586 A describes that the linearly-scratched thin metal film of each electromagnetic-wave-absorbing film has a surface resistance in a range of 50-1500 Ω/square. This near-field electromagnetic wave absorber also has excellent conductive noise absorbability in a wide frequency range from less than 1 GHz to single-digit GHz. It has been found, however, that the near-field electromagnetic wave absorber of WO 2012/090586 A has frequencies at which radiation noises are maximized. Accordingly, when this near-field electromagnetic wave absorber is put into practical use, it should be connected to a ground (GND) to prevent the radiation of the maximized noises, as in Japanese Patent 5203295.

Japanese Patent 5559668 discloses an electromagnetic wave absorber obtained by laminating pluralities of electromagnetic-wave-absorbing films via dielectric bodies in front of an electromagnetic wave reflector,
each electromagnetic-wave-absorbing film comprising a conductive material layer formed on a surface of a plastic film,
the conductive material layer of each electromagnetic-wave-absorbing film having a surface resistance in a range of 100-1000 Ω/square,
the surface resistance of the conductive material layer of a foremost electromagnetic-wave-absorbing film being larger than that of the conductive material layer of the next electromagnetic-wave-absorbing film by 100 Ω/square or more,
(a) when two electromagnetic-wave-absorbing films are contained, a ratio of the gap between the first and second electromagnetic-wave-absorbing films to the gap between the second electromagnetic-wave-absorbing film and the electromagnetic wave reflector being 100/30 to 80/70, and
(b) when three or more electromagnetic-wave-absorbing films are contained, a ratio of the gap between the first and second electromagnetic-wave-absorbing films to the gap between the second and third electromagnetic-wave-absorbing films being 100/30 to 80/70,
the conductive material layer of the electromagnetic-wave-absorbing film being provided with large numbers of substantially parallel, intermittent, linear scratches with irregular widths and intervals in two directions, and
the linear scratches having widths, 90% or more of which are in a range of 0.1-100 μm, and an average width of 1-50 μm, and intervals in a range of 0.1-200 μm and 1-100 μm on average.

Japanese Patent 5559668 describes that because the surface resistance of the conductive material layer of the foremost electromagnetic-wave-absorbing film is larger than that of the conductive material layer of the next electromagnetic-wave-absorbing film by 100 Ω/square or more, extremely higher electromagnetic wave absorbability is obtained with smaller anisotropy than when pluralities of electromagnetic-wave-absorbing films having the same surface resistance are simply laminated. However, because this electromagnetic wave absorber has a structure in which pluralities of electromagnetic-wave-absorbing films are laminated via dielectric bodies in front of the electromagnetic wave reflector (aluminum plate), it is suitable for ETC, FRID, etc., but cannot be used as a near-field electromagnetic wave absorber attached to electronic devices, etc.

### OBJECTS OF THE INVENTION

Accordingly, the first object of the present invention is to provide an electromagnetic-wave-absorbing film having high radiation noise absorbability in a wide frequency range of 100 MHz to 5 GHz, for example, and usable without connection to a ground.

The second object of the present invention is to provide a near-field electromagnetic wave absorber having higher radiation noise absorbability in a wide frequency range of 100 MHz to 5 GHz, for example, and usable without connection to a ground.

The third object of the present invention is to provide an apparatus capable of producing the above electromagnetic-wave-absorbing film efficiently.

### SUMMARY OF THE INVENTION

As a result of intensive research in view of the above objects, the inventors have found that (a) when linear scratches are formed intermittently such that their high-density regions and low-density regions are formed alternately in two directions, instead of forming linear scratches on the entire surface of a thin metal film in two directions, linear scratches in both directions cross each other, resulting in the distribution of the high-density regions of linear scratches in a lattice pattern, so that an electromagnetic-wave-absorbing film having high radiation noise absorbability in a wide frequency range of 100 MHz to 5 GHz, for example, is obtained, that (b) when the electromagnetic-wave-absorbing film having high-density regions of linear scratches in a lattice pattern is combined with an electromagnetic-wave-absorbing film having linear scratches in two directions on the entire surface of a thin metal film, a near-field electromagnetic wave absorber having higher radiation noise absorbability in a wide frequency range of 100 MHz to 5 GHz, for example, is obtained, and that (c) by changing the shapes or driving systems of pattern rolls in an apparatus forming linear scratches in two directions on the entire surface of a thin metal film, high-density regions of linear scratches and low-density regions of linear scratches are formed alternately in each of two directions. The present invention has been completed based on such findings.

Thus, the electromagnetic-wave-absorbing film of the present invention comprises a plastic film, and a thin metal film formed on a surface of the plastic film,
the thin metal film being provided with large numbers of substantially parallel linear scratches with irregular widths and intervals in two directions,
the thin metal film having high-density regions in which the linear scratches are formed at a high density and low-density regions in which the linear scratches are formed at a low density alternately in each direction, and
linear scratches in both directions are crossing each other such that the high-density regions of linear scratches are distributed in a lattice pattern.

In each direction, the high-density regions preferably have surface resistivity of 30-200 Ω/square, and the low-density regions preferably have surface resistivity of 0-20 Ω/square.

The length ratio of the high-density regions to the low-density regions is preferably 5/1-1/5 in each direction.

In each direction, the length of the high-density regions is preferably 0.2-10 mm, and the length of the low-density regions is preferably 0.2-10 mm.

The first apparatus of the present invention for producing the above electromagnetic-wave-absorbing film comprises
two pattern rolls,
a means for conveying the plastic film such that the thin metal film is brought into sliding contact with two pattern rolls, and
push rolls for pressing the thin metal film onto the pattern rolls,
the two pattern rolls being oriented oppositely with respect to the transverse direction of the plastic film, in a plane in which they are in sliding contact with the thin metal film,
an outer peripheral surface of each pattern roll being provided with linear-scratch-forming regions and non-forming regions alternately in the peripheral direction, and
the linear-scratch-forming regions having large numbers of high-hardness, fine particles on the surface.

In one embodiment of the present invention, the non-forming regions are at a position receding from the linear-scratch-forming regions radially inward in the pattern roll. The receding distance Dh of the non-forming regions is preferably 1 mm or more.

In another embodiment of the present invention, the non-forming regions do not have high-hardness, fine particles. In this case, the radius of the non-forming regions may be the same as or smaller than the radius of the linear-scratch-forming regions.

The second apparatus of the present invention for producing the above electromagnetic-wave-absorbing film comprises
two pattern rolls each having large numbers of high-hardness, fine particles on the entire outer peripheral surface,
a means for conveying the plastic film along the pattern rolls, and
push rolls arranged on both sides of each pattern roll,
two pattern rolls being oriented oppositely with respect to the transverse direction of the plastic film, in a plane in which they are in sliding contact with the thin metal film, and
the apparatus further comprising a means for moving each pattern roll and/or push rolls on both sides thereof perpendicularly to the thin metal film, such that each pattern roll is brought into sliding contact with the thin metal film intermittently.

The near-field electromagnetic wave absorber of the present invention comprises at least one plastic film and first and second thin metal films,
the first thin metal film being provided with large numbers of substantially parallel linear scratches with irregular widths and intervals in two directions, the linear scratches in each direction having high-density regions and low-density regions alternately, and the high-density regions being distributed in a lattice pattern over the entire area of the first thin metal film by the crossing of the linear scratches in both directions, and
the second thin metal film being provided with large numbers of substantially parallel, intermittent, linear scratches with irregular widths and intervals in two directions on the entire area.

In the linear scratches in each direction of the first thin metal film in the near-field electromagnetic wave absorber of the present invention, the high-density regions preferably have surface resistivity of 30-200 Ω/square, and the low-density regions preferably have surface resistivity of 0-20 Ω/square.

In the first thin metal film in each direction in the near-field electromagnetic wave absorber of the present invention, the length ratio of the high-density regions to the low-density regions is preferably 5/1-1/5.

In the first thin metal film in each direction in the near-field electromagnetic wave absorber of the present invention, the length of the high-density regions is preferably 0.2-10 mm, and the length of the low-density regions is preferably 0.2-10 mm.

The near-field electromagnetic wave absorber of the present invention preferably comprises (a) a first linearly-scratched thin metal film having large numbers of substantially parallel linear scratches formed with irregular widths and intervals in two directions, having high-density regions in which the linear scratches are formed at a high density and low-density regions in which the linear scratches are formed at a low density alternately in each direction, so that the high-density regions are distributed in a lattice pattern by the crossing of the linear scratches in both directions, and (b) a second linearly-scratched thin metal film having large numbers of substantially parallel, intermittent, linear scratches formed with irregular widths and intervals in two directions on the entire surface.

In the near-field electromagnetic wave absorber of the present invention, the first linearly-scratched thin metal film preferably has a first linear scratch group comprising the high-density regions of linear scratches and the low-density regions of linear scratches alternately in a first direction, and a second linear scratch group comprising the high-density regions of linear scratches and the low-density regions of linear scratches alternately in a second direction different from the first direction,
the first and second linear scratch groups overlapping each other, forming overlapping portions of the high-density regions, overlapping portions of the high-density regions and the low-density regions, and overlapping portions of the low-density regions on the thin metal film,
the overlapping portions of the high-density regions being distributed in a dot pattern,
a combination of the overlapping portions of the high-density regions and the overlapping portions of the high-density regions and the low-density regions constituting a lattice pattern, and
the overlapping portions of the low-density regions being distributed in a dot pattern.

The near-field electromagnetic wave absorber in the first embodiment of the present invention preferably has a structure in which the first electromagnetic-wave-absorbing film having the first thin metal film on one surface of the plastic film is adhered to the second electromagnetic-wave-absorbing film having the second thin metal film on one surface of the plastic film.

In the near-field electromagnetic wave absorber in the first embodiment of the present invention, the first and second electromagnetic-wave-absorbing films are preferably adhered to each other with the first and second thin metal films disposed inside.

The near-field electromagnetic wave absorber in the second embodiment of the present invention preferably has the first and second thin metal films on both sides of a plastic film.

In the electromagnetic-wave-absorbing film and the near-field electromagnetic wave absorber according to the present invention, the crossing angle of linear scratches in two directions is preferably 30-90°.

In the electromagnetic-wave-absorbing film and the near-field electromagnetic wave absorber according to the present invention, the thickness of the thin metal film is preferably 20-100 nm.

In the electromagnetic-wave-absorbing film and the near-field electromagnetic wave absorber according to the present invention, the thin metal film is preferably made of aluminum.

In the electromagnetic-wave-absorbing film and the near-field electromagnetic wave absorber according to the present invention, the linear scratches preferably have widths W in a range of 0.1-100 μm and 1-50 μm on average, and intervals I in a range of 0.1-500 μm and 1-200 μm on average.

### Effects of the Invention

Because the electromagnetic-wave-absorbing film of the present invention has a linear scratch distribution comprising high-density regions distributed in a lattice pattern, which is obtained by overlapping linear scratch groups having high-density linear scratch regions and low-density linear scratch regions alternately in two directions in one thin metal film, providing, it exhibits high radiation noise absorbability in a wide frequency range of 100 MHz to 5 GHz, for example. Also, the near-field electromagnetic wave absorber exhibits higher radiation noise absorbability, because it is obtained by combining an electromagnetic-wave-absorbing film having high-density regions of linear scratches distributed in a lattice pattern with an electromagnetic-wave-absorbing film having linear scratches on the entire surface of a thin metal film. When the electromagnetic-wave-absorbing film and the near-field electromagnetic wave absorber having such features according to the present invention are attached to various electronic devices in electronic appliances and communications terminals such as personal computers, cellphones, smartphones, etc. without connection to the ground, they can efficiently suppress electromagnetic noises.

Because the apparatus of the present invention is obtained by (a) changing pattern rolls in an apparatus for forming linear scratches on the entire surface of a thin metal film to those having linear-scratch-forming regions and non-forming regions alternately in the peripheral direction on the outer peripheral surface, or (b) adding a means for moving at least one of pattern rolls and push rolls on both sides thereof perpendicularly to the thin metal film to an apparatus for forming linear scratches on the entire surface of a thin metal film, it can produce the electromagnetic-wave-absorbing film of the present invention efficiently with a relatively simple structure.

### BRIEF DESCRIPTION OF THE DRAWINGS

FIG. 1(a) is a plan view schematically showing an example of first linear scratch groups constituting the electromagnetic-wave-absorbing film of the present invention.

FIG. 1(b) is a cross-sectional view taken along the line A-A in FIG. 1(a).

FIG. 2 is a plan view schematically showing another example of first linear scratch groups constituting the electromagnetic-wave-absorbing film of the present invention.

FIG. 3 is a plan view schematically showing an example of second linear scratch groups constituting the electromagnetic-wave-absorbing film of the present invention.

FIG. 4 is a plan view schematically showing an example of the electromagnetic-wave-absorbing films of the present invention.

FIG. 5 is a plan view schematically showing a portion A in a high-density overlapping portion.

FIG. 6(a) is a cross-sectional view showing an example of near-field electromagnetic wave absorbers according to the first embodiment of the present invention.

FIG. 6(b) is a cross-sectional view showing the arrangement of first and second electromagnetic-wave-absorbing films constituting the near-field electromagnetic wave absorber shown in FIG. 6(a).

FIG. 6(c) is a plan view showing an example of linearly-scratched thin metal films in the second electromagnetic-wave-absorbing film.

FIG. 7 is a cross-sectional view showing the arrangement of first and second electromagnetic-wave-absorbing films constituting another example of near-field electromagnetic wave absorbers according to the first embodiment of the present invention.

FIG. 8 is a cross-sectional view showing a near-field electromagnetic wave absorber according to the second embodiment of the present invention.

FIG. 9(a) is a perspective view showing an example of apparatuses for producing a second electromagnetic-wave-absorbing film used in the present invention.

FIG. 9(b) is a plan view showing the apparatus of FIG. 9(a).

FIG. 9(c) is a cross-sectional view taken along the line B-B in FIG. 9(b).

FIG. 9(d) is an enlarged partial plan view for explaining the principle of forming linear scratches inclined to the moving direction of the film.

FIG. 9(e) is a partial plan view showing the inclination angles of a pattern roll and a push roll to a film in the apparatus of FIG. 9(a).

FIG. 10 is a perspective view showing another example of apparatuses for producing the second electromagnetic-wave-absorbing film of the present invention.

FIG. 11(a) is a schematic cross-sectional view showing an example of pattern rolls used in the first apparatus for producing the first electromagnetic-wave-absorbing film of the present invention.

FIG. 11(b) is an enlarged partial cross-sectional view showing the linear-scratch-forming region of the pattern roll shown in FIG. 11(a).

FIG. 12 is a peripherally developed, partial cross-sectional view showing linear-scratch-forming regions and a non-forming region on the pattern roll shown in FIG. 11(a).

FIG. 13 is a schematic cross-sectional view showing another example of pattern rolls used in the first apparatus for producing the first electromagnetic-wave-absorbing film of the present invention.

FIG. 14(a) is a schematic view showing a pattern roll at an upper position in the second production apparatus for producing the first electromagnetic-wave-absorbing film of the present invention.

FIG. 14(b) is a schematic view showing a pattern roll at a lower position in the second production apparatus for producing the first electromagnetic-wave-absorbing film of the present invention.

FIG. 15 is an electron photomicrograph showing the first electromagnetic-wave-absorbing film of Example 1.

FIG. 16(a) is a plan view showing a system for evaluating the conductive noise absorbability of an electromagnetic-wave-absorbing film (near-field electromagnetic wave absorber).

FIG. 16(b) is a cross-sectional view showing a system for evaluating the conductive noise absorbability of an electromagnetic-wave-absorbing film (near-field electromagnetic wave absorber).

FIG. 17 is a graph showing the noise absorption ratio Pₗₒₛₛ/Pᵢₙ of the first electromagnetic-wave-absorbing film of Example 1.

FIG. 18 is a photograph showing the cumulative radiation noise of the first electromagnetic-wave-absorbing film of Example 1 in a range of 100 MHz to 5 GHz.

FIG. 19 is a graph showing the noise absorption ratio Pₗₒₛₛ/Pᵢₙ of the near-field electromagnetic wave absorber of Example 2.

FIG. 20 is a photograph showing the cumulative radiation noise of the near-field electromagnetic wave absorber of Example 2 in a range of 100 MHz to 5 GHz.

FIG. 21 is an electron photomicrograph showing the first electromagnetic-wave-absorbing film of Example 3.

FIG. 22 is a graph showing the noise absorption ratio Pₗₒₛₛ/Pᵢₙ of the first electromagnetic-wave-absorbing film of Example 3.

FIG. 23 is a photograph showing the cumulative radiation noise of the first electromagnetic-wave-absorbing film of Example 3 in a range of 100 MHz to 5 GHz.

FIG. 24 is a graph showing the noise absorption ratio Pₗₒₛₛ/Pᵢₙ of the near-field electromagnetic wave absorber of Example 4.

FIG. 25 is a photograph showing the cumulative radiation noise of the near-field electromagnetic wave absorber of Example 4 in a range of 100 MHz to 5 GHz.

FIG. 26 is a graph showing the noise absorption ratio Pₗₒₛₛ/Pᵢₙ of the first electromagnetic-wave-absorbing film of Comparative Example 1.

FIG. 27 is a photograph showing the cumulative radiation noise of the first electromagnetic-wave-absorbing film of Comparative Example 1 in a range of 100 MHz to 5 GHz.

FIG. 28 is a graph showing the noise absorption ratio Pₗₒₛₛ/Pᵢₙ of the near-field electromagnetic wave absorber of Comparative Example 2.

FIG. 29 is a photograph showing the cumulative radiation noise of the near-field electromagnetic wave absorber of Comparative Example 2 in a range of 100 MHz to 5 GHz.

### DESCRIPTION OF THE BEST MODE OF THE INVENTION

The embodiments of the present invention will be explained referring to the attached drawings, and it should be noted that explanations concerning one embodiment are applicable to other embodiments unless otherwise mentioned. Also, the following explanations are not restrictive, and various modifications may be made within the scope of the present invention.

### [1] Electromagnetic-Wave-Absorbing Film

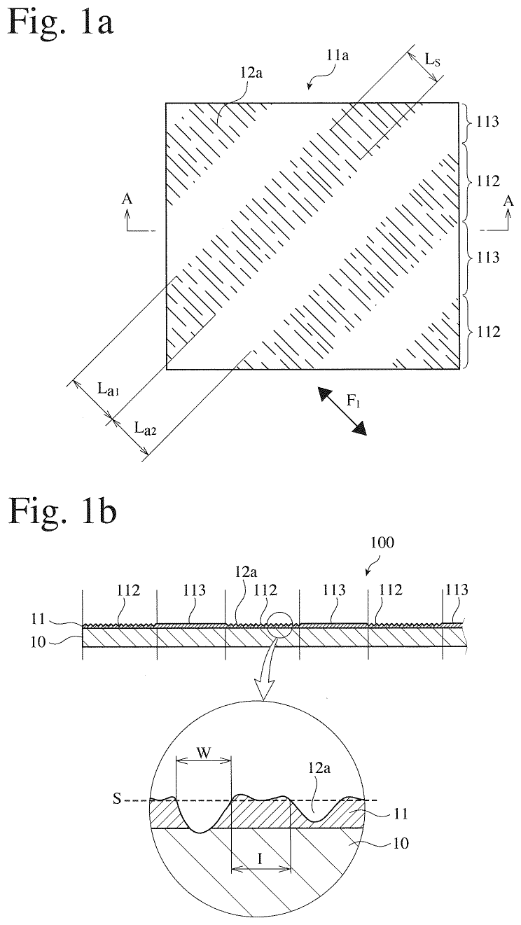

FIG. 1(a) is a plan view schematically showing an example of first linear scratch groups constituting the electromagnetic-wave-absorbing film of the present invention, and FIG. 1(b) is a cross-sectional view taken along the line A-A in FIG. 1(a). A thin metal film 11 formed on a surface of a plastic film 10 is provided with large numbers of substantially parallel linear scratches 12a with irregular widths and intervals in one (first) direction F₁, such that high-density regions 112 in which linear scratches 12a are formed and low-density regions 113 in which linear scratches 12a are substantially not formed are arranged alternately along one direction F₁. A group of linear scratches 12a in pluralities of high-density regions 112 arranged alternately in one direction F₁ is called “first linear scratch group,” and a thin metal film 11 having the first linear scratch group is called “first linearly-scratched thin metal film” 11a. The high-density regions 112 and the low-density regions 113, in which linear scratches 12a are arranged alternately along the direction F₁, form a stripe pattern. The lengths La₁ and La₂ of the high-density regions 112 and the low-density regions 113 of linear scratches 12a in the direction F₁ are determined by production methods and apparatuses.

### (1) Plastic Film

Resins forming the plastic film 10 are not particularly restrictive as long as they have sufficient strength, flexibility and workability in addition to insulation, and they may be, for instance, polyesters (polyethylene terephthalate, etc.), polyarylene sulfides (polyphenylene sulfide, etc.), polyether sulfone, polyetheretherketones, polycarbonates, acrylic resins, polystyrenes, polyolefins (polyethylene, polypropylene, etc.), etc. Among them, a polyethylene terephthalate (PET) film is preferable from the aspect of strength and cost. The thickness of the plastic film 10 may be about 10-100 μm, and preferably about 10-30 μm to make the electromagnetic-wave-absorbing film and the near-field electromagnetic wave absorber as thin as possible.

### (2) Thin Metal Film

The thin metal film 11 is made of a nonmagnetic or magnetic metal. The nonmagnetic metal may be aluminum, copper, silver, etc., and the magnetic metal may be nickel, chromium, etc. Of course, these metals may be used as pure metals or in the form of alloys. From the aspect of cost and corrosion resistance, aluminum is preferable. The thin metal film 11 can be formed by known methods such as a sputtering method, a vacuum vapor deposition method, etc. From the aspect of controlling the degree of forming linear scratches, the thickness of the thin metal film 11 is preferably 20-100 nm, more preferably 30-90 nm, and most preferably 40-80 nm.

### (3) First Linear Scratch Group

As described above, in each high-density regions 112 of the first linearly-scratched thin metal film 11a, large numbers of substantially parallel linear scratches 12a are formed in the thin metal film 11 with irregular widths and intervals in one direction F₁. As shown in FIG. 1(b), linear scratches 12a have various widths W and intervals I in a transverse direction perpendicular to the orientation direction F₁. Both widths W and intervals I of linear scratches 12a are measured at an original height of the thin metal film 11, which corresponds to the height of the surface S of the thin metal film 11 before forming linear scratches. Incidentally, the depths of linear scratches 12a are exaggerated in FIG. 1(b) for explanation.

The widths W of linear scratches 12a are preferably in a range of 0.1-100 μm, more preferably in a range of 0.1-70 μm, further preferably in a range of 0.5-50 μm, and most preferably in a range of 0.5-20 μm. The average width Way of linear scratches 12a is preferably 1-50 μm, more preferably 2-50 μm, and most preferably 5-30 μm. The intervals I of linear scratches 12a are preferably in a range of 0.1-500 μm, more preferably in a range of 0.5-200 μm, further preferably in a range of 1-100 μm, and most preferably in a range of 1-50 μm. The average interval Iav of linear scratches 12a is preferably 1-200 μm, more preferably 5-100 μm, and most preferably 10-80 μm. Incidentally, in the determination of the widths W, average width Wav, intervals I and average interval Iav, linear scratches 12a having widths of up to 0.1 μm are included. The same is true below unless otherwise mentioned.

The lengths Ls of linear scratches 12a are determined not only by sliding conditions (mainly a relative speed of the pattern roll to the plastic film, and the contact angle of the plastic film to the pattern roll), but also by the lengths of the high-density regions 112. Because there may be longitudinal gaps between linear scratches 12a in the high-density regions 112, the lengths Ls of linear scratches 12a are equal to or less than the lengths La₁ of the high-density regions 112.

### (a) Density of Forming First Linear Scratches

In general, a higher degree of forming linear scratches leads to larger widths W (proportional to depths) and smaller intervals I of linear scratches, resulting in a larger proportion (density) of linear scratches occupying the thin metal film 11. Accordingly, the degree of forming linear scratches can be expressed by the density of linear scratches. Because linear scratches are extremely small and uneven and formed at a high density, it is difficult to measure the density of linear scratches directly. Thus, noting that a higher density of linear scratches leads to larger surface resistivity and light transmittance of the thin metal film 11, the density of linear scratches is evaluated by the surface resistivity or light transmittance of the thin metal film 11.

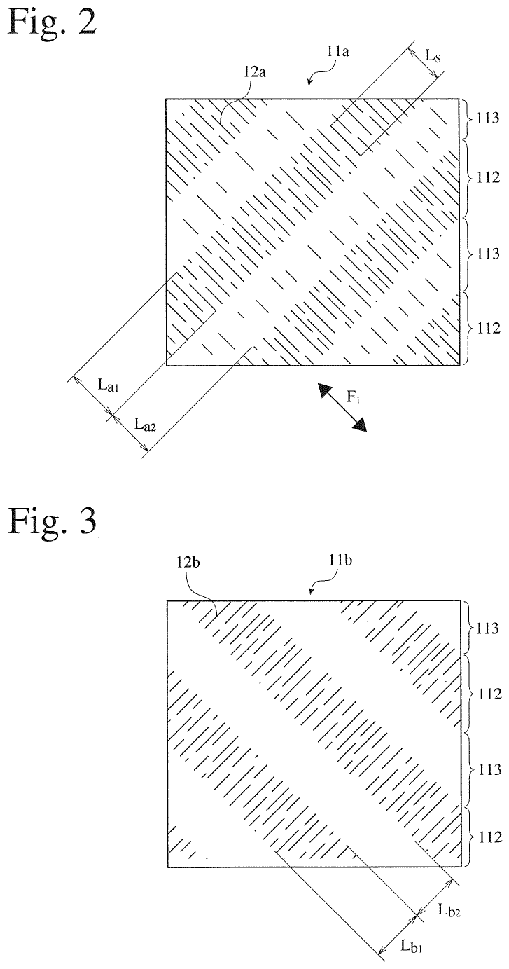

Though FIG. 1(a) does not show linear scratches 12a in the regions 113, linear scratches 12a are likely to be slightly formed in the regions 113 depending on the production method, for example, as shown in FIG. 2. However, if such linear scratches 12a are formed at a lower degree, sufficient effects of the present invention can be obtained. Accordingly, the slight formation of linear scratches 12a in the regions 113 is included in the range of the present invention. To include a case where linear scratches 12a are slightly formed in the regions 113, the regions 113 are called “low-density linear scratch regions” or simply “low-density regions,” instead of “regions having no linear scratches.” Also, the regions 112 in which linear scratches are formed at a high density are called “high-density linear scratch regions” or simply “high-density regions.”

### (i) Surface Resistivity

In the high-density regions 112, the surface resistivity of the thin metal film 11 is preferably 30-200 Ω/square. When the surface resistivity of the thin metal film 11 in the high-density regions 112 is less than 30 Ω/square or more than 200 Ω/square, the electromagnetic-wave-absorbing film cannot exhibit sufficient electromagnetic wave absorbability. On the other hand, the surface resistivity of the thin metal film 11 in the low-density regions 113 is preferably 0-20 Ω/square. The lower limit of 0 Ω/square is substantially the same as the surface resistivity of the thin metal film itself. Namely, the thin metal film 11 may be completely free of linear scratches 12a in the low-density regions 113. When the surface resistivity of the thin metal film 11 in the low-density regions 113 is more than 20 Ω/square, the effect of having low-density regions 113 is insufficient. More preferably, the surface resistivity of the thin metal film 11 is 30-150 Ω/square in the high-density regions 112, and 0-15 Ω/square in the low-density regions 113.

When the high-density regions 112 and the low-density regions 113 are very small, it is difficult to measure their surface resistivity. Accordingly, the surface resistivity of a thin metal film having linear scratches formed on the entire surface under the same conditions as in the high-density regions 112 in which linear scratches are formed in the thin metal film alternately in one direction as shown in FIG. 1(a) is measured, and used as the surface resistivity Rs1 of the high-density regions 112. Also, the surface resistivity Rs of a thin metal film 11 having both high-density regions 112 and low-density regions 113 is measured. The surface resistivity Rs2 of the low-density regions 113 can be calculated from the surface resistivities Rs1 and Rs, because the surface resistivity Rs may be regarded as the same as the sum of the surface resistivities Rs1 and Rs2 of the high-density regions 112 and the low-density regions 113.

### (ii) Light Transmittance

The light transmittance of the thin metal film 11 in the high-density regions 112 is preferably 3-10%, and more preferably 4-8%. The light transmittance of the thin metal film 11 in the low-density regions 113 is preferably 0-2.5%, and more preferably 0-2%. Incidentally, the light transmittance of 0% corresponds to a case where no linear scratches 12a are formed. The light transmittance of the thin metal film 11 in the high-density regions 112 has correlation to the surface resistivity.

### (b) Lengths of High-Density Regions and Low-Density Regions

In the direction F₁ of linear scratches 12a, the length La₁ of the high-density regions 112 is preferably 0.2-10 mm, and the length La₂ of the low-density regions 113 is preferably 0.2-10 mm. When the length La₁ of the high-density regions 112s is less than 0.2 mm, or when the length La₂ of the low-density regions 113 is more than 10 mm, the electromagnetic-wave-absorbing film exhibits too low electromagnetic wave absorbability. On the other hand, when the length La₁ of the high-density regions 112 is more than 10 mm, or when the length La₂ of the low-density regions 113 is more than 0.2 mm, sufficient effects of having the low-density regions 113 are not obtained, providing the electromagnetic-wave-absorbing film with low radiation noise absorbability. The length La₁ of the high-density regions 112 is more preferably 1-5 mm, and the length La₂ of the low-density regions 113 is more preferably 1-5 mm.

Along the direction F₁ of linear scratches 12a, the length ratio La₁/La₂ of the high-density regions 112 to the low-density regions 113 is preferably 5/1-1/5. The length ratio La₁/La₂ of less than 1/5 provides too low electromagnetic wave absorbability. On the other hand, the length ratio La₁/La₂ of more than 5/1 provides insufficient effects of having the low-density regions 113, providing the electromagnetic-wave-absorbing film with low radiation noise absorbability. To obtain isotropic electromagnetic wave absorbability, the length ratio La₁/La₂ is more preferably 2/1-1/2, and particularly preferably 1/1.

### (4) Second Linear Scratch Group

FIG. 3 is a plan view schematically showing an example of second linear scratch groups constituting the electromagnetic-wave-absorbing film of the present invention together with the first linear scratch group shown in FIG. 1. The second linear scratch group is formed in the thin metal film 11 such that it overlaps the first linear scratch group. As described later, the (second) direction F₂ of linear scratches 12b in the second linear scratch group should be different from the (first) direction F₁ of linear scratches 12a in the first linear scratch group. Incidentally, the widths W, average width Wav, intervals I and average interval Iav of linear scratches 12b in the second linear scratch group may be the same as those in the first linear scratch group. Also, the surface resistivity, light transmittance, length and length ratio of the high-density regions 112 and the low-density regions 113 in the second linear scratch group may be the same as in the first linear scratch group.

The length La₁ of the high-density regions 112 in the first linear scratch group may be the same as or different from the length Lb₁ of the high-density regions 112 in the second linear scratch group. When they are different, the ratio La₁/Lb₁ is preferably 1/2-2/1, and more preferably 2/3-3/2. Incidentally, even when they are different, the linear scratch densities of the high-density regions 112 and the low-density regions 113 in the second linear scratch group may be the same as in the first linear scratch group. In sum, the second linear scratch group may be the same as the first linear scratch group except for the direction of linear scratches.

### (5) Structure of Electromagnetic-Wave-Absorbing Film

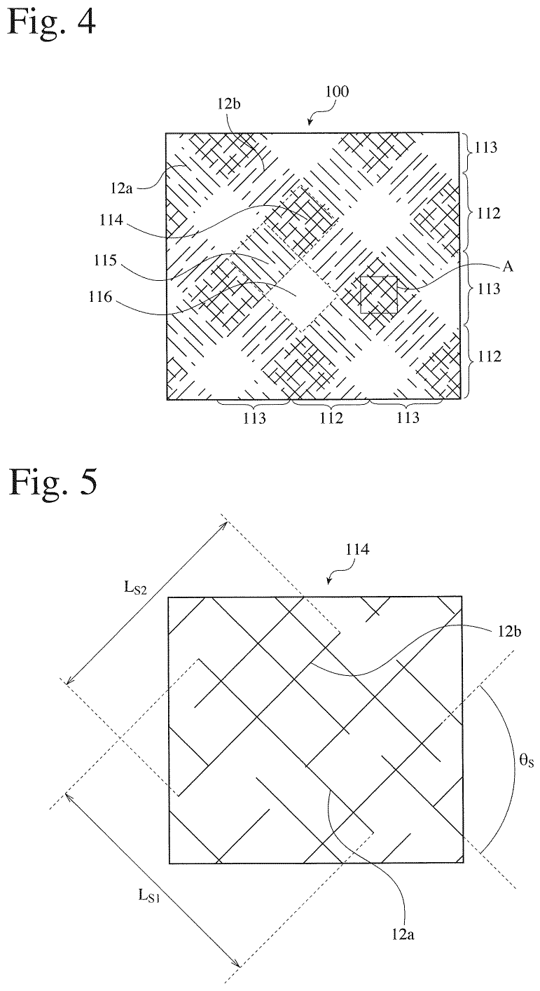

FIG. 4 is a plan view schematically showing an example of the electromagnetic-wave-absorbing films 100 of the present invention having both first and second linear scratch groups. With the first and second linear scratch groups overlapping, the overlapping portions 114 of the high-density regions 112, the overlapping portions 115 of the high-density regions 112 and the low-density regions 113 and the overlapping portions 116 of the low-density regions 113 are formed on the thin metal film 11. Simply below, the overlapping portions 114 of the high-density regions 112 are called “high-density overlapping portions,” the overlapping portions 115 of the high-density regions 112 and the low-density regions 113 are called “high-density/low-density overlapping portions,” and the overlapping portions 116 of the low-density regions 113 are called “low-density overlapping portions.”

The high-density overlapping portions 114 are distributed in a dot pattern, and a combination of the high-density overlapping portions 114 and the high-density/low-density overlapping portions 115 constitutes a lattice pattern. The low-density overlapping portions 116 are distributed in a dot pattern.

In the high-density overlapping portions 114, the linear scratches 12a in the first linear scratch group and the linear scratches 12b in the second linear scratch group are crossing each other at a crossing angle θs as schematically shown in FIG. 5. The crossing angle θs of the linear scratches 12a, 12b is preferably 30-90°, more preferably 60-90°, most preferably 80-90°, and particularly 90°. As the crossing angle θs is closer to 90°, the electromagnetic wave absorbability is more isotropic.

In FIG. 5, Ls₁, Ls₂ indicate the lengths of the linear scratches 12a, 12b. Though the length Ls₁ of the linear scratches 12a may be different from the length Ls₂ of the linear scratches 12b, they are preferably the same to obtain isotropic electromagnetic wave absorbability. When the length Ls₁ of the linear scratches 12a is different from the length Ls₂ of the linear scratches 12b, the length ratio Ls₁/Ls₂ is preferably 1/2-2/1, and more preferably 2/3-3/2.

In the high-density/low-density overlapping portions 115, either one of the linear scratches 12a, 12b are formed mainly, and the other linear scratches are not substantially formed. Accordingly, the high-density/low-density overlapping portions 115 contribute to the improvement of radiation noise absorbability, though exhibiting lower conductive noise absorbability than that of the high-density overlapping portions 114. Though most linear scratches are oriented in one direction in each of the high-density/low-density overlapping portions 115, most linear scratches in adjacent high-density/low-density overlapping portions 115 are oriented in a different direction by the crossing angle θs, so that the overall electromagnetic wave absorbability of the electromagnetic-wave-absorbing film is substantially isotropic.

Because of substantially no linear scratches 12a, 12b, the low-density overlapping portions 116 act like the thin metal film 11 itself, exhibiting large radiation noise absorbability. Electric current generated from electromagnetic noises absorbed by the low-density overlapping portions 116 flows to adjacent high-density/low-density overlapping portions 115 and the high-density overlapping portions 114, and attenuated there.

Because the high-density overlapping portions 114 are distributed in a lattice pattern via the high-density/low-density overlapping portions 115 by the crossing of linear scratches 12a, 12b in the electromagnetic-wave-absorbing film 100 of the present invention, the high-density regions 112 are also distributed in a lattice pattern on the thin metal film 11. Because of the lattice distribution of the high-density regions 112, the electromagnetic-wave-absorbing film 100 of the present invention can exhibit good radiation noise absorbability while securing sufficient conductive noise absorbability.

### [2] Near-Field Electromagnetic Wave Absorber

The near-field electromagnetic wave absorber of the present invention comprises at least one plastic film and first and second thin metal films,
the first thin metal film being provided with large numbers of substantially parallel linear scratches with irregular widths and intervals in two directions, having high-density regions in which the linear scratches are formed at a high density and low-density regions in which the linear scratches are formed at a low density alternately in each direction,
the high-density regions being distributed in a lattice pattern by the crossing of the linear scratches in both directions, and
   the second thin metal film being provided with large numbers of substantially parallel, intermittent, linear scratches with irregular widths and intervals in two directions on the entire area.

Specifically, the near-field electromagnetic wave absorber of the present invention comprises (a) a first linearly-scratched thin metal film having large numbers of substantially parallel linear scratches formed with irregular widths and intervals in two directions, having high-density regions in which the linear scratches are formed at a high density and low-density regions in which the linear scratches are formed at a low density alternately in each direction, so that the high-density regions are distributed in a lattice pattern by the crossing of the linear scratches in both directions, and (b) a second linearly-scratched thin metal film having large numbers of substantially parallel, intermittent, linear scratches formed with irregular widths and intervals in two directions on the entire surface.

The first linearly-scratched thin metal film preferably has a first linear scratch group comprising the high-density regions of linear scratches and the low-density regions of linear scratches alternately in a first direction, and a second linear scratch group comprising the high-density regions of linear scratches and the low-density regions of linear scratches alternately in a second direction different from the first direction,
the first and second linear scratch groups overlapping each other, forming overlapping portions of the high-density regions, overlapping portions of the high-density regions and the low-density regions, and overlapping portions of the low-density regions on the thin metal film,
the overlapping portions of the high-density regions being distributed in a dot pattern,
a combination of the overlapping portions of the high-density regions and the overlapping portions of the high-density regions and the low-density regions constituting a lattice pattern, and
the overlapping portions of the low-density regions being distributed in a dot pattern.

### (1) First Embodiment

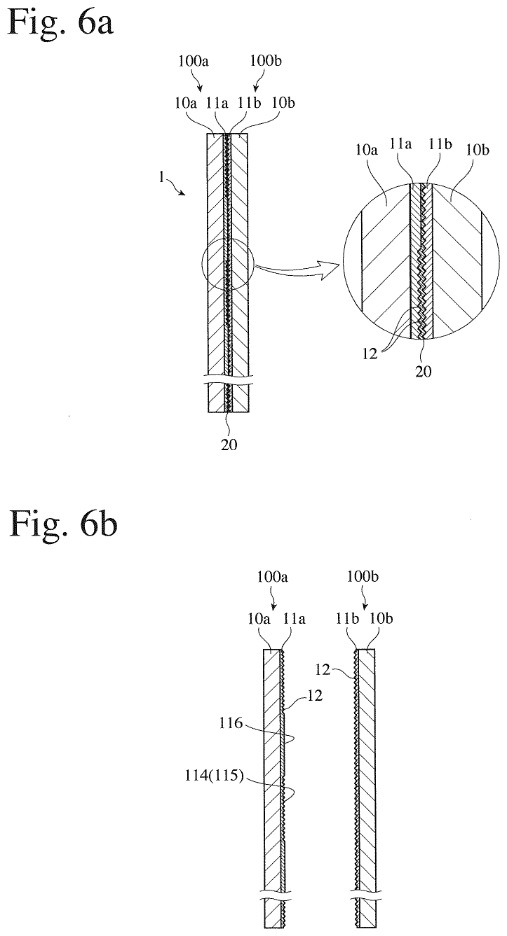

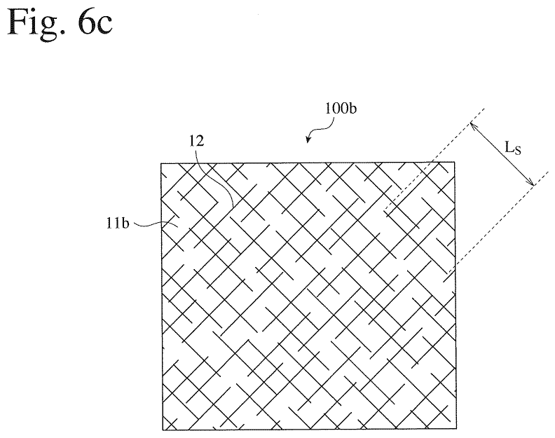

As shown in FIGS. 6(a) and 6(b), an example of the near-field electromagnetic wave absorbers according to the first embodiment of the present invention comprises a first electromagnetic-wave-absorbing film 100a having the first linearly-scratched thin metal film 11a on a plastic film 10a, and a second electromagnetic-wave-absorbing film 100b having the second linearly-scratched thin metal film 11b on a plastic film 10b, which are adhered to each other via an adhesive layer 20. Because the first and second linearly-scratched thin metal films 11a, 11b are facing each other in this example, the adhesive layer 20 is nonconductive to prevent their conduction. A very thin adhesive layer 20 can provide the electromagnetic coupling of the first and second linearly-scratched thin metal films 11a and 11b. Though the adhesive layer 20 can be formed by an adhesive, it may be formed by heat seal or a double-sided tape.

The second electromagnetic-wave-absorbing film 100b may be the same as the first electromagnetic-wave-absorbing film 100a, except that large numbers of substantially parallel linear scratches are formed with irregular widths and intervals in two directions on the entire surface of the thin metal film 11. FIG. 6(c) shows an example of the linearly-scratched thin metal films 11b in the second electromagnetic-wave-absorbing film 100b.

The widths W of linear scratches 12 in the second linearly-scratched thin metal film 11b are preferably in a range of 0.1-100 μm, more preferably in a range of 0.1-70 μm, further preferably in a range of 0.5-50 μm, and most preferably in a range of 0.5-20 μm. The average width Way of linear scratches 12 is preferably 1-50 μm, further preferably 2-50 μm, and most preferably 5-30 μm. The intervals I of linear scratches 12 are preferably in a range of 0.1-500 μm, more preferably in a range of 0.5-200 μm, most preferably in a range of 1-100 μm, and particularly in a range of 1-50 μm. The average interval Iav of linear scratches 12 is preferably 1-200 μm, more preferably 5-100 μm, and most preferably 10-80 μm.

Because the lengths Ls of the linear scratches 12 in the second linearly-scratched thin metal film 11b are determined by sliding conditions (mainly relative speeds of a pattern roll and a plastic film), most of them are substantially the same (substantially equal to the average length), unless the sliding conditions are changed. The lengths Ls of the linear scratches 12 may be practically about 1-100 mm, and preferably 2-10 mm, though not particularly restrictive.

The crossing angle θs of linear scratches 12 in two directions in the second linearly-scratched thin metal film 11b is preferably 30-90°, more preferably 45-90°, most preferably 60-90°, and particularly 90°.

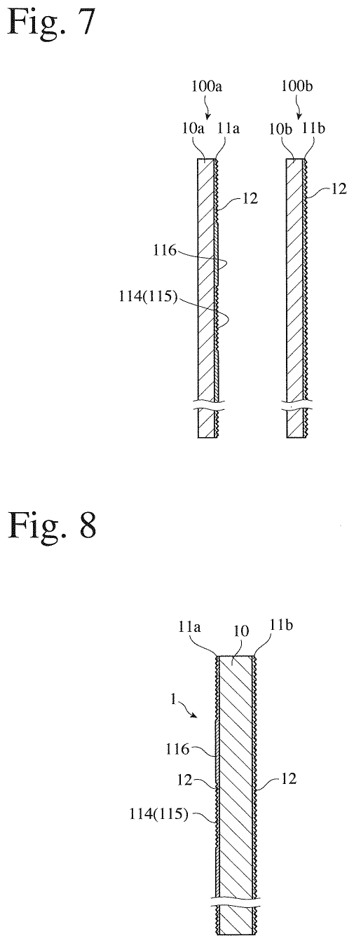

Instead of the first and second linearly-scratched thin metal films 11a, 11b opposing each other, the first and second electromagnetic-wave-absorbing films 100a, 100b may be adhered such that each linearly-scratched thin metal film 11a, 11b is positioned on the same side of each plastic film as shown in FIG. 7.

### (2) Second Embodiment

FIG. 8 shows a near-field electromagnetic wave absorber in the second embodiment of the present invention. This near-field electromagnetic wave absorber comprises a plastic film 10, and first and second linearly-scratched thin metal films 11a, 11b formed on both sides of the plastic film 10. The first and second linearly-scratched thin metal films 11a, 11b themselves may be the same as in the first embodiment.

### [3] Production Apparatus of Electromagnetic-Wave-Absorbing Film

Because the first linearly-scratched thin metal film has a more complicated structure than that of the second linearly-scratched thin metal film, an apparatus for producing the second electromagnetic-wave-absorbing film comprising the second linearly-scratched thin metal film will be explained first.

### (1) Production Apparatus of Second Electromagnetic-Wave-Absorbing Film

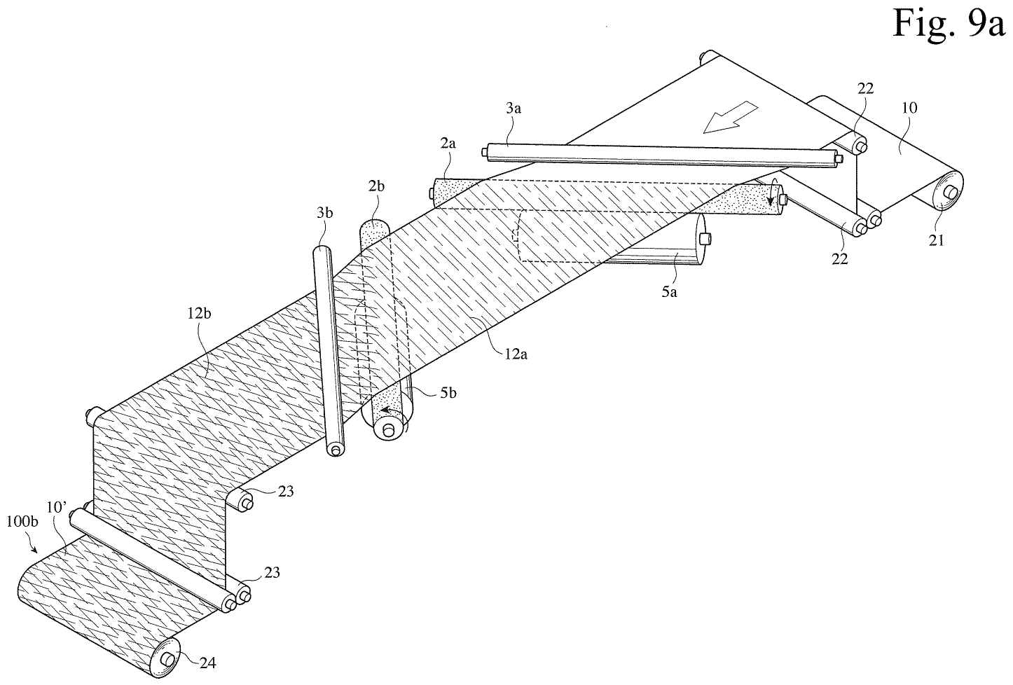

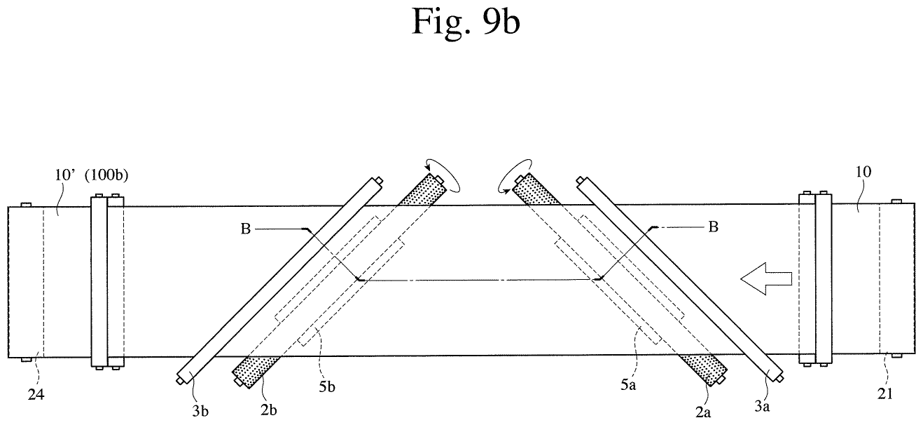

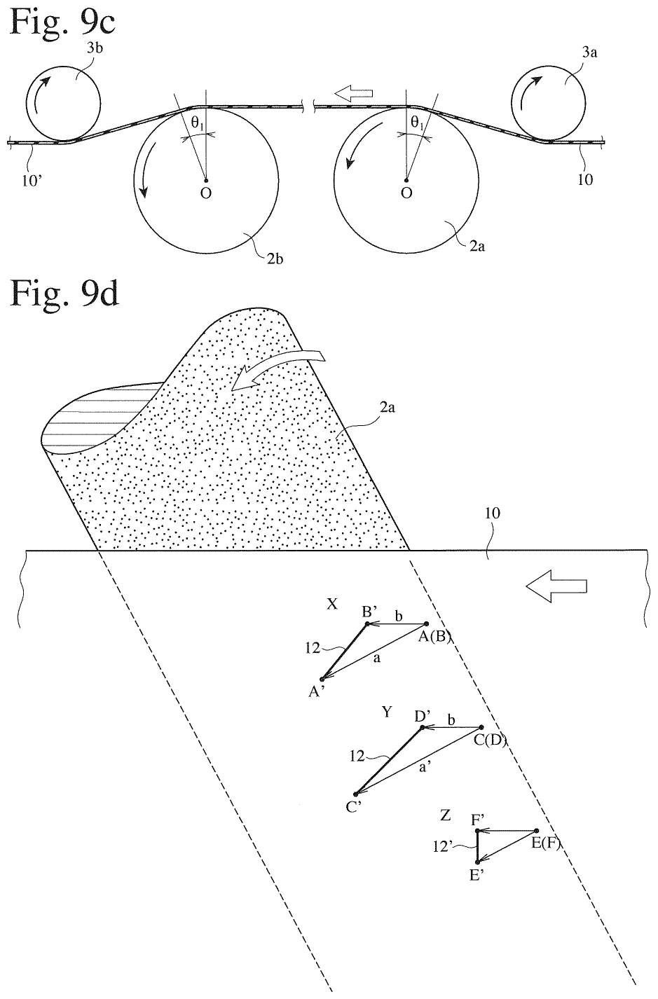

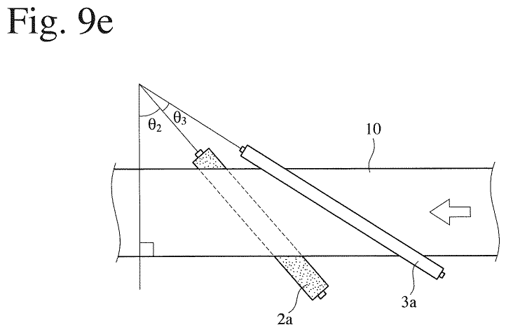

FIGS. 9(a) to 9(e) show an example of apparatuses for producing the second electromagnetic-wave-absorbing film 100b. The depicted apparatus comprises (a) a reel 21 from which a plastic film 10 having a thin metal film is wound off, (b) a first pattern roll 2a inclined to the transverse direction of the plastic film 10, (c) a first push roll 3a arranged upstream of the first pattern roll 2a on the opposite side, (d) a second pattern roll 2b inclined to the transverse direction of the plastic film 10 in an opposite direction to the first pattern roll 2a and arranged on the same side as the first pattern roll 2a, (e) a second push roll 3b arranged downstream of the second pattern roll 2b on the opposite side, and (f) a reel 24, around which a plastic film 10′ having a linearly-scratched thin metal film (second electromagnetic-wave-absorbing film 100b) is wound. In addition, pluralities of guide rolls 22, 23 are arranged at predetermined positions. Each pattern roll 2a, 2b is supported by a backup roll (for instance, rubber roll) 5a, 5b to prevent bending. Though one push roll 3a, 3b is arranged near each pattern roll 2a, 2b in the apparatus shown in FIG. 9(a), a pair of push rolls may be arranged on both sides of each pattern roll 2a, 2b.

As shown in FIG. 9(c), because each push roll 3a, 3b comes into contact with the thin metal film of the plastic film 10 at a lower position than the position at which it is brought into sliding contact with each pattern roll 2a, 2b, the plastic film 10 is pushed by each pattern roll 2a, 2b. By adjusting the height of each push roll 3a, 3b with this condition met, the pressing power of each pattern roll 2a, 2b to the thin metal film can be controlled. Specifically, the lower position of each push roll 3a, 3b increases the pressing power of each pattern roll 2a, 2b to the thin metal film of the plastic film 10, forming deeper linear scratches in the thin metal film (increasing the degree of forming linear scratches in the thin metal film). Oppositely, the higher position of each push roll 3a, 3b decreases the pressing power of each pattern roll 2a, 2b to the thin metal film of the plastic film 10, forming shallower linear scratches in the thin metal film of the plastic film 10 (decreasing the degree of forming linear scratches in the thin metal film).

Increase in the depth of linear scratches generally results in a smaller amount of a metal remaining in the thin metal film, providing the linearly-scratched thin metal film with higher surface resistivity. Accordingly, the surface resistivity of the linearly-scratched thin metal film can be adjusted by changing the pressing power of each pattern roll 2a, 2b to the thin metal film of the plastic film 10. Incidentally, deeper linear scratches tend to have larger widths, resulting in smaller intervals between adjacent linear scratches. The pressing power of each pattern roll 2a, 2b to the plastic film 10 can be adjusted by displacing each pattern roll 2a, 2b toward or away from the plastic film 10. The displacement of each pattern roll 2a, 2b can be conducted by a driving mechanism (not shown) attached to each pattern roll 2a, 2b.

FIG. 9(d) shows the principle that linear scratches 12 are formed with inclination to the moving direction of the plastic film 10. Because the pattern roll 2a is inclined to the moving direction of the plastic film 10, the moving direction (rotation direction) of fine, hard particles on the pattern roll 2a differs from the moving direction of the plastic film 10. After a fine, hard particle on a point A on the pattern roll 2a comes into contact with the thin metal film of the plastic film 10 to form a scratch B at an arbitrary time as shown by X, the fine, hard particle moves to a point A′, and the scratch B moves to a point B′, in a predetermined period of time. While the fine, hard particle moves from the point A to the point A′, the scratch B is continuously formed, resulting in a linear scratch 12a extending from the point A′ to the point B′.

The directions and crossing angle θs of linear scratches 12 formed by the first and second pattern rolls 2a, 2b can be adjusted by changing the angle of each pattern roll 2a, 2b to the plastic film 10, and/or the peripheral speed of each pattern roll 2a, 2b relative to the moving speed of the plastic film 10. For instance, when the peripheral speed a of the pattern roll 2a relative to the moving speed b of the plastic film 10 increases, the linear scratches 12 can be inclined 450 to the moving direction of the plastic film 10 like a line C′D′ as shown by Y in FIG. 9(d). Similarly, the peripheral speed a of the pattern roll 2a can be changed by changing the inclination angle θ₂ of the pattern roll 2a to the transverse direction of the plastic film 10. This is true of the pattern roll 2b. Accordingly, with both pattern rolls 2a, 2b adjusted, the directions of linear scratches 12 can be changed.

Because each pattern roll 2a, 2b is inclined to the plastic film 10, sliding with each pattern roll 2a, 2b applies a force in a transverse direction to the plastic film 10. Accordingly, to prevent the lateral movement of the plastic film 10, the height and/or angle of each push roll 3a, 3b to each pattern roll 2a, 2b are preferably adjusted. For instance, the proper adjustment of a crossing angle θ₃ between the axis of the pattern roll 2a and the axis of the push roll 3a provides the pressing power with such a transverse distribution as to cancel transverse components, thereby preventing the lateral movement of the plastic film 10. The adjustment of a distance between the pattern roll 2a and the push roll 3a also contributes to the prevention of the lateral movement of the plastic film 10. To prevent the lateral movement and breakage of the plastic film 10, the rotation directions of the first and second pattern rolls 2a, 2b inclined to the transverse direction of the plastic film 10 are preferably the same as the moving direction of the plastic film 10.

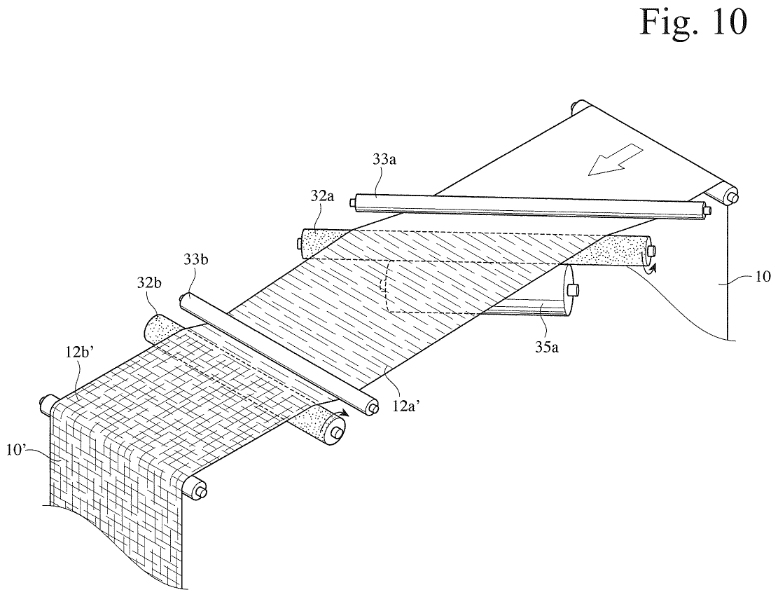

FIG. 10 shows another example of apparatuses for forming rectangularly crossing linear scratches. This apparatus is different from the apparatus shown in FIGS. 9(a) to 9(e) in that a second pattern roll 32b is parallel to the transverse direction (rectangular to the moving direction) of the plastic film 10. Accordingly only portions different from those in the apparatus shown in FIGS. 9(a) to 9(e) will be explained. The rotation direction of the second pattern roll 32b may be the same as or opposite to the moving direction of the plastic film 10. Also, a second push roll 33b may be upstream or downstream of the second pattern roll 32b. This apparatus is suitable for forming rectangularly crossing linear scratches, with linear scratches 12′ (line E′F′) parallel to the transverse direction of the plastic film 10 as shown by Z in FIG. 9(d).

The moving speed of the plastic film 10 is preferably 5-200 m/minute, and the peripheral speed of the pattern roll is preferably 10-2,000 m/minute. The inclination angles θ₂ of the pattern rolls are preferably 20° to 60°, particularly about 45°. The tension (proportional to the pressing power) of the plastic film 10 is preferably 0.05-5 kgf/cm width.

The pattern roll is preferably a roll having fine particles with sharp edges and Mohs hardness of 5 or more on the surface, for instance, the diamond roll described in JP 2002-59487 A. Because the widths of linear scratches are determined by the sizes of fine particles, 90% or more of fine diamond particles preferably have sizes in a range of 0.1-100 μm, more preferably in a range of 0.1-70 μm. The fine diamond particles are attached to the roll surface preferably in an area ratio of 30% or more. The fine diamond particles are fixed preferably by a layer of a metal such as nickel, etc.

### (2) Production Apparatus of First Electromagnetic-Wave-Absorbing Film

### (a) First Production Apparatus

The first production apparatus has basically the same structure as that of the production apparatus of the second electromagnetic-wave-absorbing film, except that an outer peripheral surface of each pattern roll has linear-scratch-forming regions and non-forming regions alternately in the peripheral direction, and that the linear-scratch-forming regions have large numbers of high-hardness, fine particles on the surface. Accordingly, the above pattern roll will be explained in detail.

FIG. 11(a) shows an example of pattern rolls used in the first production apparatus. This pattern roll 102 comprises a roll body 102a, and linear-scratch-forming regions 102b and non-forming regions 102c alternately formed with predetermined intervals on an outer peripheral surface of the roll body 102a. As shown in FIG. 11(b), each linear-scratch-forming region 102b comprises large numbers of high-hardness, fine particles 102d, and a fixing layer 102e for holding them. As in the production apparatus of the above second electromagnetic-wave-absorbing film, the high-hardness, fine particles 102d are preferably fine diamond particles, and the fixing layer 102e is preferably a layer of a metal such as nickel, etc. In order that linear scratches are completely or substantially not formed in the thin metal film 11 even when the thin metal film 11 comes to the closest position to the non-forming regions 102c by the rotation of the pattern roll 102, the non-forming regions 102c are preferably (a) regions free of the fixing layer 102e holding large numbers of high-hardness, fine particles 102d, or (b) regions constituted only by the fixing layer 102e (having no high-hardness, fine particles 102d).

The center angle α1 of each linear-scratch-forming region 102b is preferably 30-90°, and more preferably 45-90°. The center angle α2 of each non-forming region 102c is preferably 30-90°, and more preferably 45-90°. Because four linear-scratch-forming regions 102b and four non-forming regions 102c are alternately arranged in the depicted example, α1+α2 is 90°, though not restrictive.

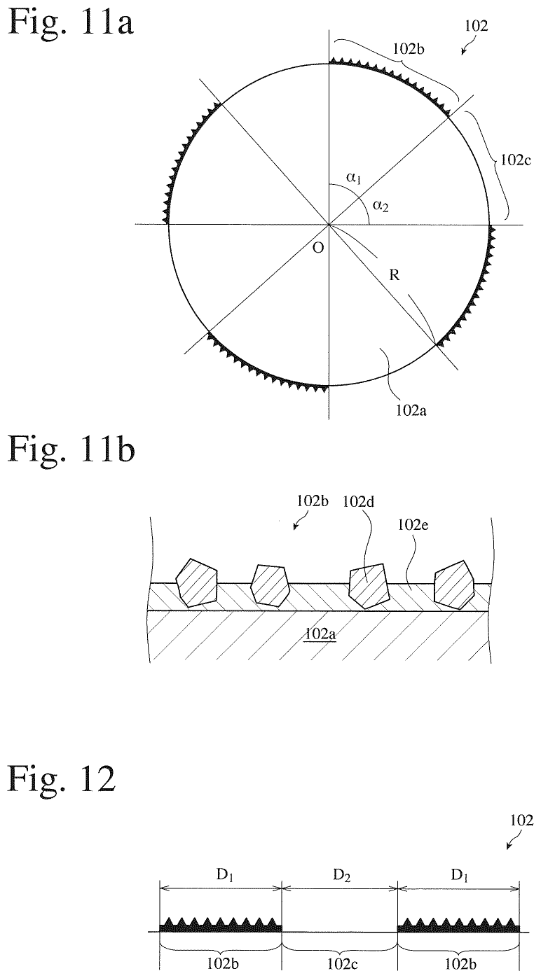

As shown in FIG. 12, the peripheral lengths D1, D2 of each linear-scratch-forming region 102b and each non-forming region 102c are determined by their center angles α1, α2 and the radius R of the roll body 102a. They are preferably 0.2-10 mm, and more preferably 1-5 mm.

The radius R of the roll body 102a is preferably 3-6 cm. When the radius R is more than 6 cm, the sliding contact length of the pattern roll 102 with the thin metal film 11 is too long, failing to obtain short high-density linear scratch regions. On the other hand, when the radius R is less than 3 cm, the roll body 102a does not have sufficient toughness. The radius R of the roll body 102a is more preferably 3-5 cm.

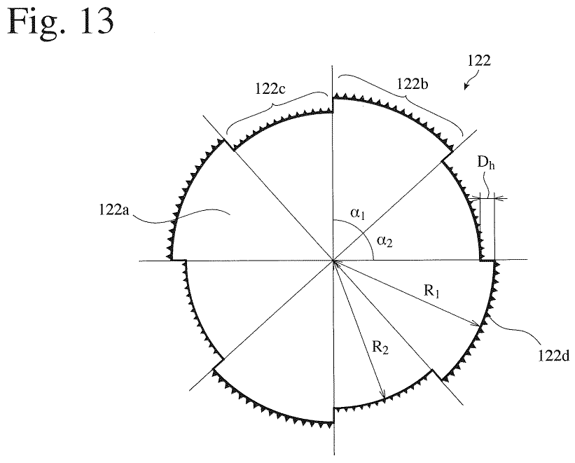

FIG. 13 shows another example of pattern rolls used in the first production apparatus. This pattern roll 122 comprises a roll body 122a having large-diameter regions 122b and small-diameter regions 122c alternately along the outer peripheral surface, linear-scratch-forming regions 122d being formed in the large-diameter regions 122b of the roll body 122a, and the small-diameter regions 122c act as non-forming regions. The linear-scratch-forming regions 122d may be the same as the linear-scratch-forming regions 102b in the above pattern roll 102. Though a fixing layer holding large numbers of high-hardness, fine particles need not be formed in the small-diameter regions 122c, it may be formed in the small-diameter regions 122c for production efficiency. The center angle (peripheral length) ratio of each large-diameter region 122b to each small-diameter region 122c may be the same as the center angle (peripheral length) ratio of linear-scratch-forming region 102b to each non-forming region 102c in the above pattern roll 102.

When the fixing layer holding large numbers of high-hardness, fine particles is formed in the small-diameter regions 122c, the difference Dh between the radius R₁ of each large-diameter region 122b and the radius R₂ of each small-diameter region 122c is preferably 1 mm or more. When the difference Dh is less than 1 mm, high-hardness, fine particles in the small-diameter regions 122c may be brought into strong sliding contact with the thin metal film 11, so that linear scratches are formed too densely in the low-density regions of the first electromagnetic-wave-absorbing film. The difference Dh is more preferably 2-5 mm.

The radius R₁ of each large-diameter region 122b of the roll body 122a is also preferably 3-6 cm, and more preferably 3-5 cm.

### (b) Second Production Apparatus

The second production apparatus has basically the same structure as that of the production apparatus of the second electromagnetic-wave-absorbing film, except that it comprises a means for moving at least one of a pattern roll and push rolls perpendicularly to a thin metal film such that each pattern roll is intermittently brought into sliding contact with the thin metal film. Accordingly, the perpendicular driving of a pattern roll and/or push rolls will be explained in detail.

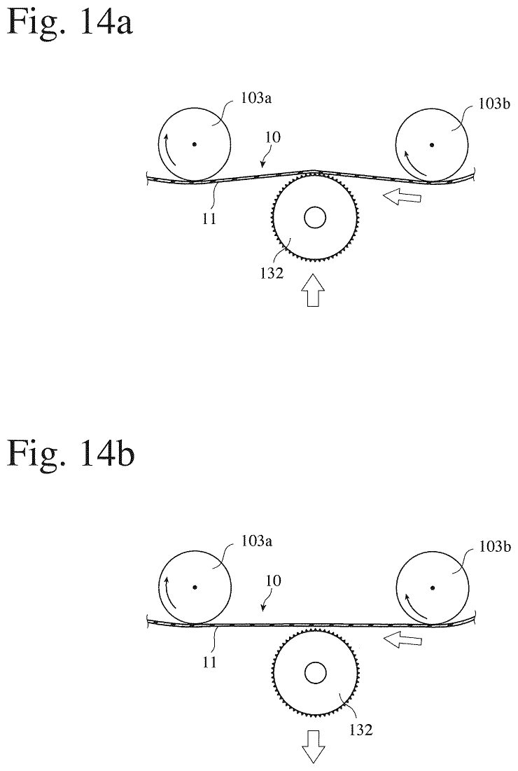

FIGS. 14(a) and 14(b) show an example in which rotation shafts of a pair of push rolls 103a, 103b are fixed, and a rotation shaft of a pattern roll 132 moves perpendicularly to the thin metal film 11 with a predetermined time interval by a driving apparatus (not shown). The pattern roll 132 has large numbers of high-hardness, fine particles on the entire outer peripheral surface, like the pattern rolls 2a, 2b used in the production apparatus of the second electromagnetic-wave-absorbing film. The plastic film 10 is kept at a constant height by a pair of push rolls 103a, 103b.

In a state shown in FIG. 14(a), the pattern roll 132 at an upper position is pushed to come into sliding contact with the thin metal film 11 of the plastic film 10, so that linear scratches are formed in the thin metal film 11. Then, the pattern roll 132 moves to a lower position as shown in FIG. 14(b), so that it separates from the thin metal film 11, forming substantially no linear scratches in the thin metal film 11. Because linear scratches are alternately formed by such intermittent perpendicular movement of each pattern roll 132, the first and second linear scratch groups can be alternately formed in the thin metal film 11 in the linear scratch direction. The lengths of the high-density regions and the low-density regions in the first and second linear scratch groups can be adjusted by the time interval of the perpendicular movement of each pattern roll 132.

For the same reasons as above, the radius R of the pattern roll 132 is also preferably 3-6 cm, and more preferably 3-5 cm.

Instead of the perpendicular movement of the pattern roll 132, a pair of push rolls 103a, 103b may move perpendicularly to form the high-density regions and the low-density regions alternately. Also, when the pattern roll 132 and a pair of push rolls 103a, 103b are driven perpendicularly in an opposite direction, namely when a pair of push rolls 103a, 103b are driven downward while the pattern roll 132 moves upward, or when a pair of push rolls 103a, 103b are driven upward while the pattern roll 132 moves downward, the switching of the sliding contact of the pattern roll 132 with the thin metal film 11 can be made faster, forming narrower high-density regions and low-density regions (shorter in the linear scratch direction).

The present invention will be explained in more detail referring to Examples below without intention of restricting it thereto.

### Example 1

### (1) Production of First Electromagnetic-Wave-Absorbing Film

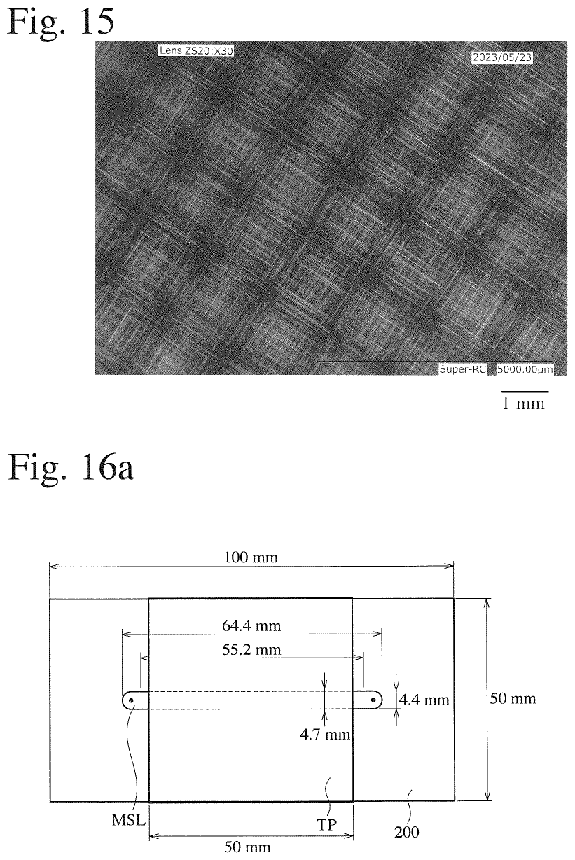

A pair of pattern rolls 102, 102 having electroplated fine diamond particles having a particle size distribution of 50-80 μm were used in place of a pair of pattern rolls 2a, 2b in the apparatus shown in FIG. 9(a), to provide the first production apparatus. High-density regions and low-density regions of linear scratches having the following characteristics were alternately formed in one direction in a thin aluminum film as thick as 60 nm vapor-deposited on a PET film as thick as 16 μm, by a pattern roll 102 on the upstream side of the first production apparatus, to produce a first linear scratch group. Then, a second linear scratch group having high-density regions and low-density regions of linear scratches in a different direction was formed over the first linear scratch group by a pattern roll 102 on the downstream side under the same conditions as the first linear scratch group, to obtain a first electromagnetic-wave-absorbing film. The crossing angle θs of linear scratches in the first and second linear scratch groups was 90°. An electron photomicrograph of this first electromagnetic-wave-absorbing film is shown in FIG. 15.

Linear scratches in the first and second linear scratch groups had the same characteristics as described below except for their directions.

### High-Density Regions

Linear scratches:
   Range of width W: 0.5-50 μm
   Average width Wav: 30 μm
   Range of transverse interval I: 1-50 μm
   Average transverse interval Iav: 40 μm
   Average length Lav: 1 mm
   Length in orientation direction: 2 mm
Low-density regions^{(l)}
   Length in orientation direction: 2 mm
      Note: (1) Because only slight linear scratches were formed in the low-density regions, only the length of the low-density regions in the orientation direction was measured.

### (a) Measurement of Surface Resistivity

The surface resistivity Rs of a thin aluminum film having the first linear scratch group having high-density regions and low-density regions of linear scratches was measured. Also, the surface resistivity of a thin aluminum film having linear scratches formed on the entire surface under the same conditions as the high-density regions was measured, and used as the surface resistivity Rs1 of the high-density regions. The surface resistivity Rs2 of the low-density regions was calculated from the surface resistivities Rs and Rs1. For the measurement of surface resistivity, a sheet resistance/surface resistivity meter “EC-80P” available from Napson Corporation was used. Incidentally, the surface resistivity of the second linear scratch group was regarded as the same as that of the first linear scratch group.

### (b) Measurement of Light Transmittance

The light transmittance Lt of a thin aluminum film having the first linear scratch group having high-density regions and low-density regions of linear scratches was measured. Also, the light transmittance of a thin aluminum film having linear scratches formed on the entire surface under the same conditions as in the high-density regions was measured, and used as the surface resistivity Lt1 of the high-density region. The light transmittance Lt2 of the low-density regions was calculated from the light transmittances Lt and Lt1. For the measurement of light transmittance, a laser thrubeam sensor (IB-30) available from Keyence Corporation was used. Incidentally, the light transmittance of the second linear scratch group was regarded as the same as that of the first linear scratch group.

### High-Density Regions

Surface resistivity: 90 Ω/square
Light transmittance: 4.5%

### Low-Density Regions

Surface resistivity: 8 Ω/square
Light transmittance: 1.5%

### (2) Measurement of Conductive Noise Absorption Ratio

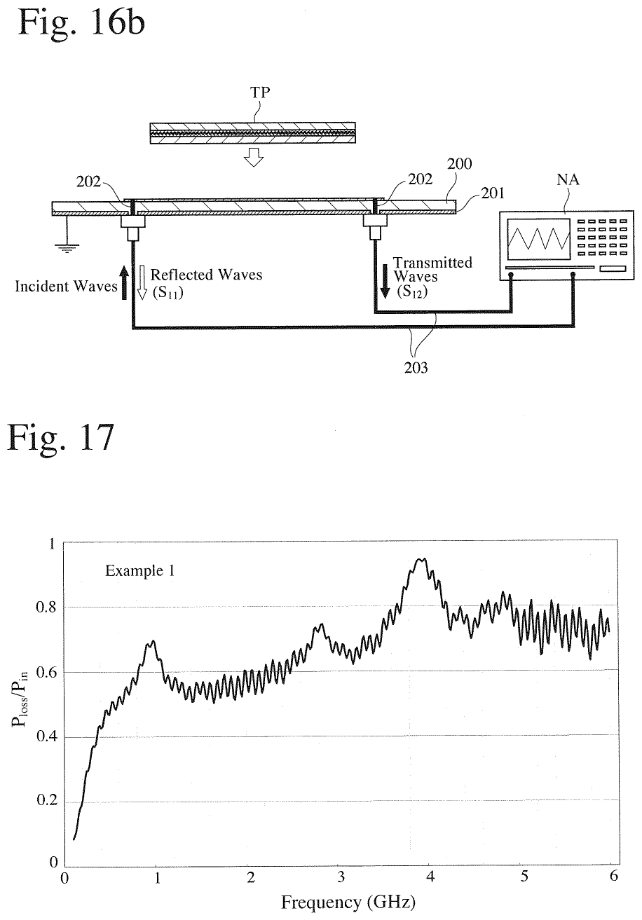

A test piece TP1 (50 mm×50 mm) was cut out of the first electromagnetic-wave-absorbing film. In a near-field electromagnetic wave evaluation system comprising a microstripline MSL (64.4 mm×4.4 mm) of 50Ω, an insulation substrate 200 supporting the microstripline MSL, a ground electrode 201 attached to a lower surface of the insulation substrate 200, conductor pins 202, 202 connected to both ends of the microstripline MSL, a network analyzer NA, and coaxial cables 203, 203 for connecting the network analyzer NA to the conductor pins 202, 202 as shown in FIGS. 16(a) and 16(b), the test piece TP1 was attached to an upper surface of the insulation substrate 200 by an adhesive, such that the center of the test piece TP1 was aligned with the center of microstripline MSL. Reflected wave power S₁₁ and transmitted wave power S₁₂ were measured with incident waves of 0.1-6 GHz supplied to the microstripline MSL, to determine a noise absorption ratio Pₗₒₛₛ/Pᵢₙ from S₁₁ and S₁₂. The results are shown in FIG. 17. As is clear from FIG. 17, the electromagnetic-wave-absorbing film of Example 1 exhibited a good balance of a noise absorption ratio Pₗₒₛₛ/Pᵢₙ and radiation noise absorbability, though the noise absorption ratio Pₗₒₛₛ/Pᵢₙ was slightly poorer than that of Comparative Example 1 described later.

### (3) Measurement of Radiation Noise

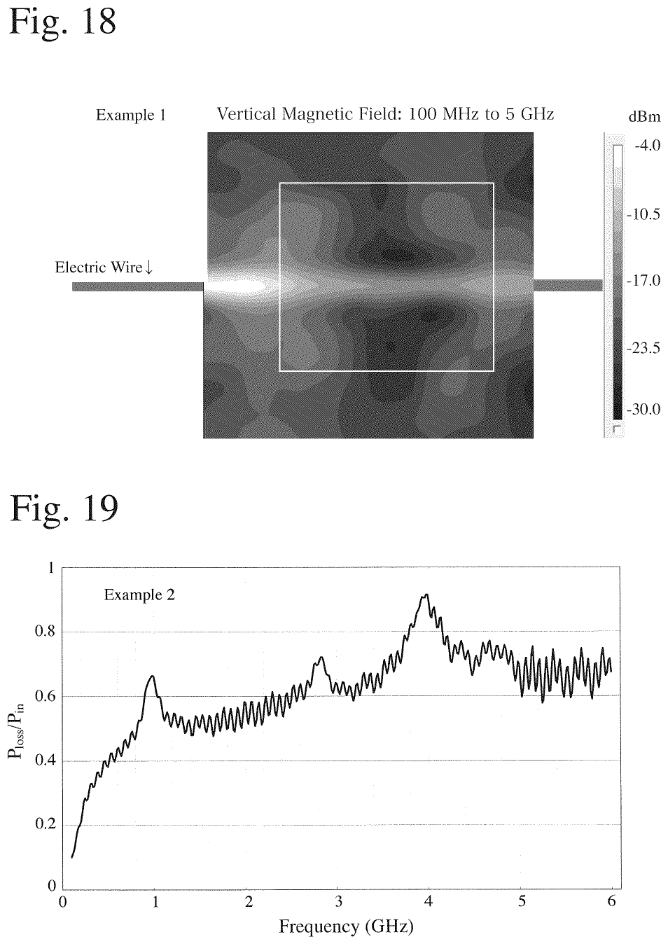

A test piece TP2 (40 mm×40 mm) cut out of the first electromagnetic-wave-absorbing film was scanned by an EMC noise scanner (WM7400) available from Morita Tech Co. Ltd. in a frequency range from 0.03 GHz to 7 GHz, to measure radiation noises. FIG. 18 shows the cumulative radiation noises of the test piece of Example 1. In FIG. 18, the position of the test piece is shown by a white frame. In the photographs of cumulative radiation noises below, the position of the test piece is omitted because of no change.

As is clear from FIG. 18, cumulative radiation noises of −10 dBm or more were not substantially observed in a frequency range of 100 MHz to 5 GHz. This confirms that the first electromagnetic-wave-absorbing film of Example 1 has excellent radiation noise absorbability in a frequency range of 100 MHz to 5 GHz.

### Example 2

### (1) Production of Second Electromagnetic-Wave-Absorbing Film

Using an apparatus having the structure shown in FIG. 9(a), which comprised pattern rolls 2a, 2b having electroplated fine diamond particles having a particle size distribution of 50-80 μm, linear scratches having the characteristics described below were formed on the entire surface of the same thin aluminum film as in Example 1 in two directions, to obtain a second electromagnetic-wave-absorbing film.
Range of width W: 0.5-50 μm
Average width Wav: 30 μm
Range of transverse interval I: 1-5 μm
Average transverse interval Iav: 40 μm
Average length Lav: 1 mm
Crossing angle θs: 90°

The surface resistivity and light transmittance of the second electromagnetic-wave-absorbing film having crossing linear scratches on the entire surface were measured by the same methods as in Example 1. As a result, they were 25 Ω/square and 3%, respectively.

### (2) Adhesion of First and Second Electromagnetic-Wave-Absorbing Films

The above second electromagnetic-wave-absorbing film was adhered to the first electromagnetic-wave-absorbing film produced in Example 1 by a nonconductive adhesive, to obtain a near-field electromagnetic wave absorber shown in FIG. 6(a). The thickness of the adhesive layer 20 was 5 μm.

### (3) Conductive Noise Absorbability and Radiation Noise Absorbability of Near-Field Electromagnetic Wave Absorber

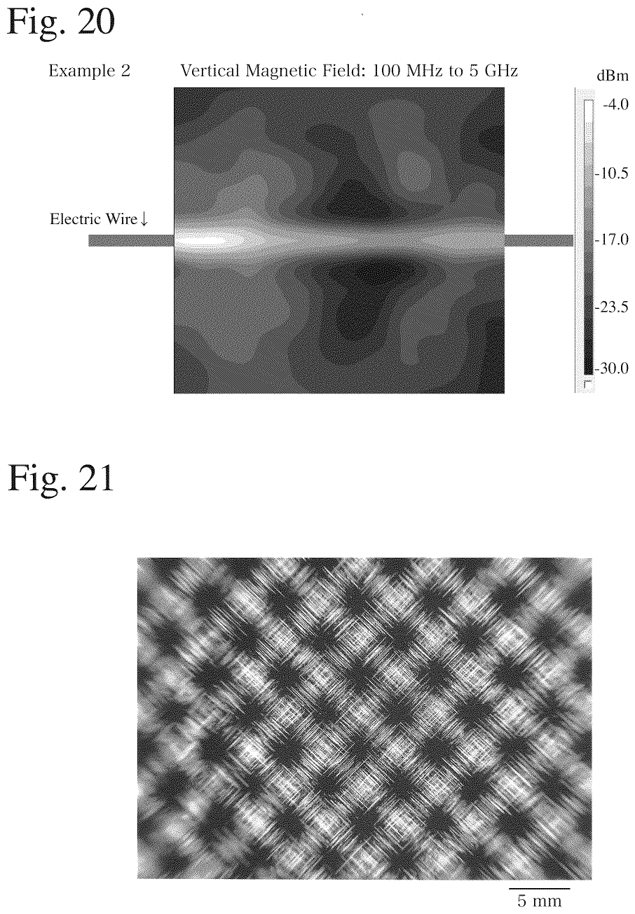

The noise absorption ratio Pₗₒₛₛ/Pᵢₙ and radiation noise of the near-field electromagnetic wave absorber measured in the same manner as in Example 1 are shown in FIGS. 19 and 20. As is clear from FIGS. 19 and 20, the near-field electromagnetic wave absorber of Example 2 exhibited excellent radiation noise absorbability and sufficient conductive noise absorbability.

### Example 3

### (1) Production of First Electromagnetic-Wave-Absorbing Film

A second production apparatus was obtained by exchanging a pair of pattern rolls 2a, 2b in the apparatus shown in FIG. 9(a) to a pair of pattern rolls 132, 132 each having a means (not shown) for perpendicularly moving its rotation shaft. Each pattern roll 132, 132 had electroplated fine diamond particles having a particle size distribution of 50-80 μm on the entire outer peripheral surface. Each pattern roll 132, 132 was driven such that it moved up and down with a predetermined time interval while the plastic film 10 having a thin metal film 11 was conveyed.

Using a pattern roll 132 positioned on the upstream side of the second production apparatus, high-density linear scratch regions and low-density linear scratch regions having the characteristics described below were formed in the same thin aluminum film as in Example 1 alternately in one direction, to produce a first linear scratch group. Next, using a pattern roll 132 positioned on the downstream side, a second linear scratch group having high-density linear scratch regions and low-density linear scratch regions in another direction was formed over the first linear scratch group under the same conditions as for the first linear scratch group, to obtain a first electromagnetic-wave-absorbing film. The crossing angle θs of linear scratches in the first and second linear scratch groups was 90°. An electron photomicrograph of this first electromagnetic-wave-absorbing film is shown in FIG. 21.

The linear scratches in the first and second linear scratch groups had the same characteristics except for their directions as described below.

### High-Density Regions

Linear scratches:
   Range of width W: 0.5-50 μm
   Average width Wav: 35 μm
   Range of transverse interval I: 1-50 μm
   Average transverse interval Iav: 30 μm
   Average length Lav: 1 mm
Length in orientation direction: 2 mm
Low-Density Regions⁽¹⁾
   Length in orientation direction: 2 mm
      Note: (1) Because only slight linear scratches were formed in the low-density regions, only the length of the low-density regions in the orientation direction was measured.

The surface resistivity and light transmittance of the high-density regions and the low-density regions in the first linear scratch group were measured by the same methods as in Example 1. Incidentally, the surface resistivity and light transmittance of the second linear scratch group were regarded as the same as those of the first linear scratch group.

### High-Density Regions

Surface resistivity: 150 Ω/square
Light transmittance: 6%

### Low-Density Regions

Surface resistivity: 3 Ω/square
Light transmittance: 1%

### (2) Conductive Noise Absorbability and Radiation Noise Absorbability of First Electromagnetic-Wave-Absorbing Film

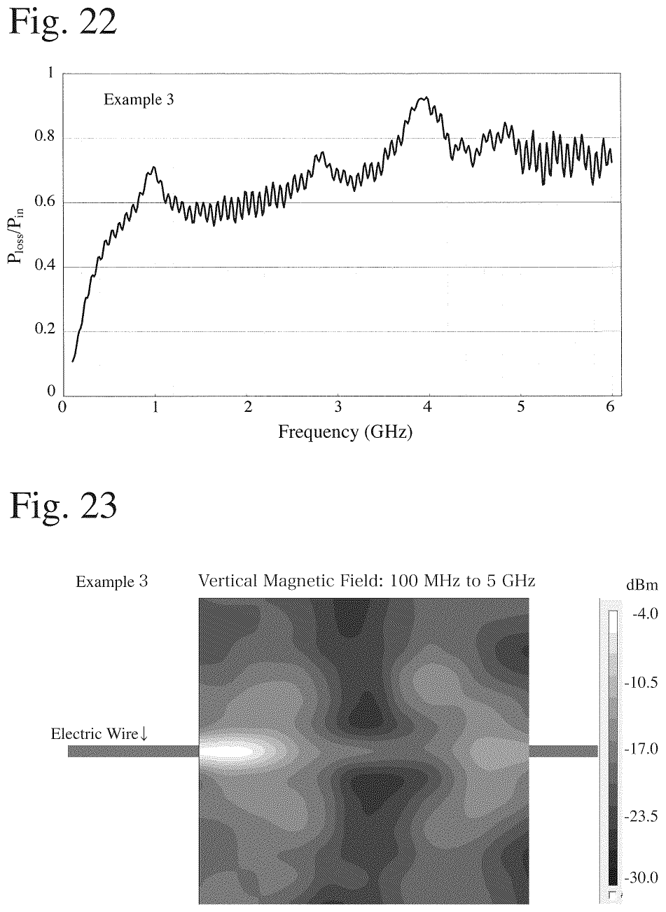

The noise absorption ratio Pₗₒₛₛ/Pᵢₙ and radiation noise of the first electromagnetic-wave-absorbing film measured by the same methods as in Example 1 are shown in FIGS. 22 and 23, respectively. As is clear from FIGS. 22 and 23, the first electromagnetic-wave-absorbing film of Example 3 exhibited excellent radiation noise absorbability and sufficient conductive noise absorbability.

### Example 4

### (1) Adhesion of First and Second Electromagnetic-Wave-Absorbing Films

The first electromagnetic-wave-absorbing film of Example 3 was adhered to the second electromagnetic-wave-absorbing film of Example 2 by a nonconductive adhesive, to produce a near-field electromagnetic wave absorber shown in FIG. 6(a). The resultant adhesive layer 20 was as thick as 5 μm.

### (2) Conductive Noise Absorbability and Radiation Noise Absorbability of Near-Field Electromagnetic Wave Absorber

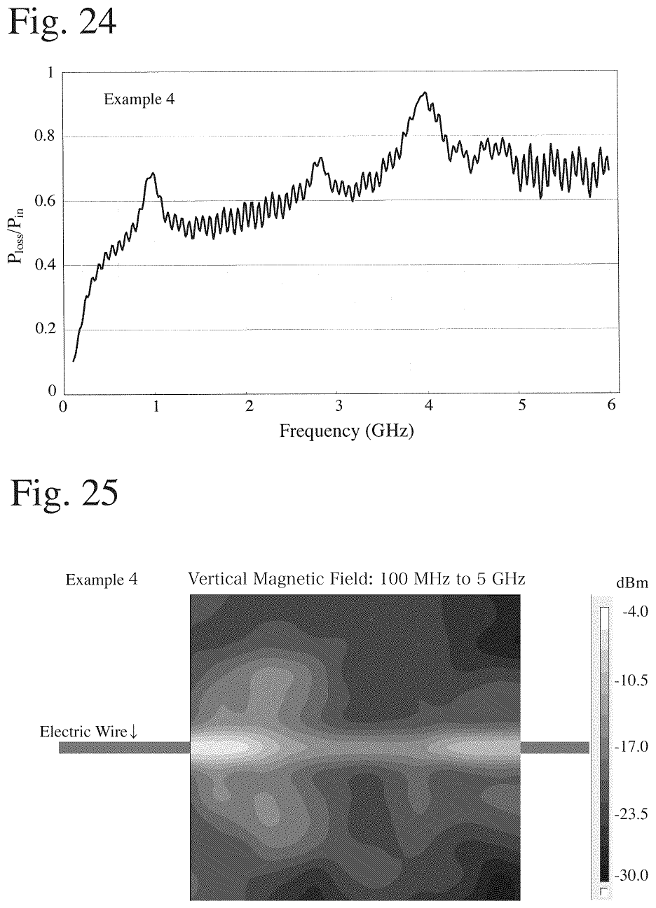

The noise absorption ratio Pₗₒₛₛ/Pᵢₙ and radiation noise of the near-field electromagnetic wave absorber measured by the same methods as in Example 1 are shown in FIGS. 24 and 25. As is clear from FIGS. 24 and 25, the near-field electromagnetic wave absorber of Example 4 exhibited excellent radiation noise absorbability and sufficient conductive noise absorbability.

### Comparative Example 1

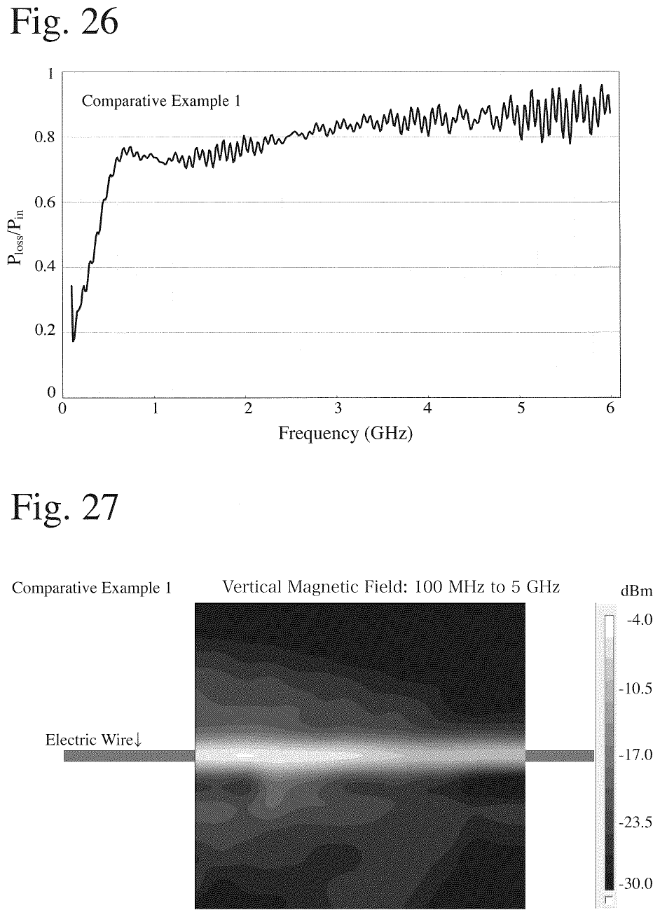

The noise absorption ratio Pₗₒₛₛ/Pᵢₙ and radiation noise of test pieces TP1 and TP2 cut out of one second electromagnetic-wave-absorbing film produced in Example 2 were measured by the same methods as in Example 1. The results are shown in FIGS. 26 and 27. As is clear from FIGS. 26 and 27, the electromagnetic-wave-absorbing film of Comparative Example 1 exhibited extremely poorer radiation noise absorbability than those of Examples 1 and 3, though it had excellent conductive noise absorbability.

### Comparative Example 2

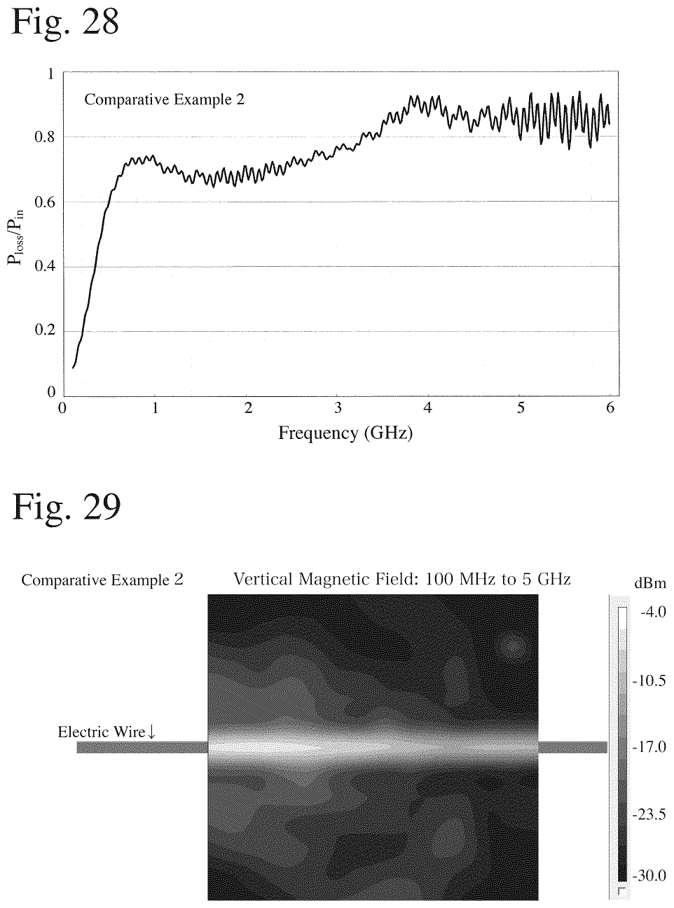

The noise absorption ratio Pₗₒₛₛ/Pᵢₙ and radiation noise of test pieces TP1 and TP2 cut out of a near-field electromagnetic wave absorber obtained by adhering two second electromagnetic-wave-absorbing films produced in Example 2 were measured by the same methods as in Example 1. The results are shown in FIGS. 28 and 29. As is clear from FIGS. 28 and 29, the near-field electromagnetic wave absorber of Comparative Example 2 exhibited extremely poorer radiation noise absorbability than those of Examples 2 and 4, though it had good conductive noise absorbability.

### DESCRIPTION OF REFERENCE NUMERALS

1: Near-field electromagnetic wave absorber
10, 10a, 10b: Plastic film
11: Thin metal film
11a: First linearly-scratched thin metal film
11b: Second linearly-scratched thin metal film
12, 12a, 12b: Linear scratches
2a, 2b, 32a, 32b: Pattern roll for producing a second electromagnetic-wave-absorbing film
3a, 3b, 103a, 103b: Push roll
20: Adhesive layer
100a: First electromagnetic-wave-absorbing film
100b: Second electromagnetic-wave-absorbing film
102: An example of pattern rolls used in the first apparatus for producing the first electromagnetic-wave-absorbing film
102a: Roll body
102b: Linear-scratch-forming regions
102c: Non-forming regions
102d: High-hardness, fine particles
102e: Fixing layer
112: High-density region
113: Low-density region
114: Overlapping portion of high-density regions
115: Overlapping portion of high-density region and low-density region
116: Overlapping portion of low-density regions
122: Another example of pattern rolls used in the first apparatus for producing the first electromagnetic-wave-absorbing film
122a: Roll body
122b: Large-diameter region
122c: Small-diameter region
122d: Linear-scratch-forming region
132: Pattern roll used in the second apparatus for producing the first electromagnetic-wave-absorbing film
α1: Center angle of linear-scratch-forming region
α2: Center angle of non-forming region
R: Radius of roll body
R₁: Radius of large-diameter region
R₂: Radius of small-diameter region

What is claimed is:

1. An electromagnetic-wave-absorbing film comprising a plastic film and a thin metal film formed on a surface of said plastic film,
said thin metal film being provided with large numbers of substantially parallel linear scratches with irregular widths and intervals in two directions,
said linear scratches having high-density regions and low-density regions alternately in each direction, and
said high-density regions being distributed in a lattice pattern by the crossing of linear scratches in both directions.

2. The electromagnetic-wave-absorbing film according to claim 1, wherein said high-density regions have surface resistivity of 30-200 Ω/square, and said low-density regions have surface resistivity of 0-20 Ω/square.

3. The electromagnetic-wave-absorbing film according to claim 1, wherein the crossing angle of linear scratches in two directions is 30-90°.

4. The electromagnetic-wave-absorbing film according to claim 1, wherein the length ratio of said high-density regions to said low-density regions is 5/1-1/5 in each direction.

5. The electromagnetic-wave-absorbing film according to claim 1, wherein said linear scratches have widths in a range of 0.1-100 μm and 2-50 μm on average, and intervals in a range of 0.1-500 μm and 10-100 μm on average.

6. An apparatus for producing an electromagnetic-wave-absorbing film comprising a plastic film and a thin metal film formed on a surface of said plastic film, said thin metal film being provided with large numbers of substantially parallel linear scratches with irregular widths and intervals in two directions, with high-density regions and low-density regions of linear scratches alternately in each direction, and said high-density regions being distributed in a lattice pattern by the crossing of linear scratches in both directions,
said apparatus comprising
two pattern rolls,
a means for conveying said plastic film such that said thin metal film is brought into sliding contact with two pattern rolls, and
push rolls for pressing said thin metal film onto said pattern rolls,
said two pattern rolls being oriented oppositely with respect to the transverse direction of said plastic film, in a plane in which they are in sliding contact with said thin metal film,
the outer peripheral surface of each pattern roll being provided with linear-scratch-forming regions and non-forming regions alternately in the peripheral direction, and
said linear-scratch-forming regions having large numbers of high-hardness, fine particles on the surface.

7. The apparatus for producing an electromagnetic-wave-absorbing film according to claim 6, wherein said non-forming regions of said pattern roll is at a position receding from said linear-scratch-forming regions radially inward.

8. The apparatus for producing an electromagnetic-wave-absorbing film according to claim 7, wherein said non-forming regions of said pattern roll is at a position receding from said linear-scratch-forming regions by 1 mm or more radially inward.

9. An apparatus for producing an electromagnetic-wave-absorbing film comprising a plastic film and a thin metal film formed on a surface of said plastic film, said thin metal film being provided with large numbers of substantially parallel linear scratches with irregular widths and intervals in two directions, with high-density regions and low-density regions of linear scratches alternately in each direction, and said high-density regions being distributed in a lattice pattern by the crossing of linear scratches in both directions,
said apparatus comprising
two pattern rolls each having large numbers of high-hardness, fine particles on the entire outer peripheral surface,
a means for conveying said plastic film along said pattern rolls, and
push rolls arranged on both sides of each pattern roll,
said two pattern rolls being oriented oppositely with respect to the transverse direction of said plastic film, in a plane in which they are in sliding contact with said thin metal film, and
said apparatus further comprising a means for moving each pattern roll and/or push rolls on both sides thereof perpendicularly to said thin metal film, such that each pattern roll is brought into sliding contact with said thin metal film intermittently.

10. A near-field electromagnetic wave absorber comprising at least one plastic film and first and second thin metal films,
said first thin metal film being provided with large numbers of substantially parallel linear scratches with irregular widths and intervals in two directions, having high-density regions in which said linear scratches are formed at a high density and low-density regions in which said linear scratches are formed at a low density alternately in each direction,
said high-density regions being distributed in a lattice pattern by the crossing of said linear scratches in both directions, and
said second thin metal film being provided with large numbers of substantially parallel, intermittent, linear scratches with irregular widths and intervals in two directions on the entire area.

11. The near-field electromagnetic wave absorber according to claim 10, wherein said high-density regions have surface resistivity of 30-200 Ω/square, and said low-density regions have surface resistivity of 0-20 Ω/square.

12. The near-field electromagnetic wave absorber according to claim 10, wherein in said first thin metal film, the length ratio of said high-density regions to said low-density regions is 5/1-1/5 in each direction.

13. The near-field electromagnetic wave absorber according to claim 10, wherein a first electromagnetic-wave-absorbing film having said first thin metal film on one surface of a plastic film is adhered to a second electromagnetic-wave-absorbing film having said second thin metal film on one surface of a plastic film.

14. The near-field electromagnetic wave absorber according to claim 13, wherein said first and second electromagnetic-wave-absorbing films are adhered to each other with said first and second thin metal films disposed inside.

15. The near-field electromagnetic wave absorber according to claim 10, wherein said first and second thin metal films are formed on both sides of a plastic film.

16. The near-field electromagnetic wave absorber according to claim 10, wherein the crossing angle of linear scratches in two directions is 30-90° in each of said first and second thin metal films.

17. The near-field electromagnetic wave absorber according to claim 10, wherein in said first and second thin metal films, said linear scratches have widths in a range of 0.1-100 μm and 2-50 μm on average, and intervals in a range of 0.1-500 μm and 10-100 μm on average.

18. The near-field electromagnetic wave absorber according to claim 10, wherein said first linearly-scratched thin metal film has a first linear scratch group comprising said high-density regions of linear scratches and said low-density regions of linear scratches alternately in a first direction, and a second linear scratch group comprising said high-density regions of linear scratches and said low-density regions of linear scratches alternately in a second direction different from said first direction,
said first and second linear scratch groups overlapping each other, forming overlapping portions of said high-density regions, overlapping portions of said high-density regions and said low-density regions, and overlapping portions of said low-density regions on said thin metal film,
said overlapping portions of said high-density regions being distributed in a dot pattern,
a combination of said overlapping portions of said high-density regions and said overlapping portions of said high-density regions and said low-density regions constituting a lattice pattern, and
said overlapping portions of said low-density regions being distributed in a dot pattern.
